(19) United States
(12) Patent Application Publication
(10) Pub. No.: US 2025/0280529 A1
(43) Pub. Date: Sep. 4, 2025

(54) SEMICONDUCTOR DEVICES AND FABRICATION METHODS THEREOF

(71) Applicant: Yangtze Memory Technologies Co., Ltd., Wuhan (CN)

(72) Inventors: Zichen LIU, Wuhan (CN); Wei LIU, Wuhan (CN); Yaqin LIU, Wuhan (CN)

(21) Appl. No.: 18/633,399

(22) Filed: Apr. 11, 2024

(30) Foreign Application Priority Data
Mar. 4, 2024 (CN) 202410241997.3

(51) Int. Cl. H10B 12/00; H01L 23/528

(52) U.S. Cl. CPC H10B 12/395; H01L 23/5283; H10B 12/0383; H10B 12/0387; H10B 12/053; H10B 12/315; H10B 12/482; H10B 12/485

(57) ABSTRACT

Systems, devices, and methods for managing three-dimensional (3D) semiconductor devices are provided. In one aspect, a semiconductor device includes an array structure having a plurality of memory cells. A memory cell of the plurality of memory cells includes a transistor and a capacitor that are stacked together. The transistor includes a transistor body, a first terminal, a second terminal, and a gate structure. The first terminal of the transistor is in contact with a first electrode of the capacitor along the first direction. The gate structure includes a conductive film having an angled or curved end closer to the first terminal of the transistor than the second terminal of the transistor.

### CROSS-REFERENCE TO RELATED APPLICATIONS

This application claims priority to Chinese Patent Application No. 202410241997.3, filed on Mar. 4, 2024, which is hereby incorporated by reference in its entirety.

### TECHNICAL FIELD

The present disclosure relates to semiconductor devices and fabrication processes for semiconductor devices.

### BACKGROUND

Semiconductor devices, e.g., memory devices, can have various structures to increase a density of memory cells and lines on a chip. For example, three-dimensional (3D) memory devices are attractive due to their capability to increase an array density by stacking more layers within a similar footprint. A 3D memory device normally includes a memory array of memory cells and peripheral circuits for facilitating operations of the memory array. The memory cells can include vertical structures.

### SUMMARY

The present disclosure describes methods, devices, systems and techniques for managing three-dimensional (3D) semiconductor devices.

One aspect of the present disclosure features a semiconductor device, including: an array structure comprises a plurality of memory cells. A memory cell of the plurality of memory cells comprises a transistor and a capacitor that are stacked together along a first direction. The transistor comprises a transistor body, a first terminal, a second terminal, and a gate structure. The first terminal and the second terminal being on opposite ends of the transistor body along the first direction. The gate structure extends along the first direction and is adjacent to the transistor body along a second direction perpendicular to the first direction. The first terminal of the transistor is in contact with a first electrode of the capacitor along the first direction. The gate structure comprises a conductive film having an angled or curved end closer to the first terminal of the transistor than the second terminal of the transistor.

In some implementations, the transistor body comprises a first body and a second body that are in contact with each other along the second direction. The second body has a higher electron mobility than the first body, and the second body is closer to the gate structure than the first body.

In some implementations, the first body comprises amorphous silicon, and the second body comprises at least one of polycrystalline silicon, indium gallium zinc oxide (IGZO), or indium gallium silicon oxide (IGSO).

In some implementations, the transistor body comprises at least one of polycrystalline silicon, indium gallium zinc oxide (IGZO), or indium gallium silicon oxide (IGSO).

In some implementations, the array structure comprises an isolating region that is between transistors of two adjacent memory cells of the plurality of memory cells. The isolating region has a first end close to first terminals of the transistors and a second end close to second terminals of the transistors, and the first end has a smaller size than the second end.

In some implementations, the capacitor comprises a dielectric structure extending along the first direction, and the first electrode is on at least one surface of the dielectric structure. The dielectric structure has a first end and a second end opposite to each other along the first direction. The first end is closer to the first terminal of the transistor than the second end, and the first end has a greater size than the second end.

In some implementations, the capacitor further comprises a second electrode and a capacitor body between the first electrode and the second electrode. The first electrode encloses the dielectric structure, the capacitor body covers the first electrode, and the second electrode covers the capacitor body. The array structure comprises supporting structures extending along the second direction and being distributed along the first direction between the first electrode and the second electrode or between first electrodes of two adjacent capacitors.

In some implementations, the array structure further comprises a plurality of bit lines. One of the plurality of bit lines is in contact with the second terminal of the transistor, and adjacent bit lines are isolated by a corresponding isolating region.

In some implementations, the array structure is integrated in a first die, and the semiconductor device further comprises a second die. The first die comprises at least one conductive interconnection, through which the one of the plurality of bit lines is coupled to a control circuit in the second die. A surface of a cover layer over the plurality of bit lines in the first die is in contact with a surface of the control circuit in the second die, and the plurality of bit lines is closer to the second die than the capacitor.

Another aspect of the present disclosure features a semiconductor device including: an array structure comprising a plurality of memory cells. A memory cell of the plurality of memory cells comprises a transistor and a capacitor that are stacked together along a first direction. The transistor comprises a transistor body, a first terminal, a second terminal, and a gate structure. The first terminal and the second terminal are on opposite ends of the transistor body along the first direction. The gate structure extends along the first direction and is adjacent to the transistor body along a second direction perpendicular to the first direction. The transistor body comprises at least one of polycrystalline silicon, indium gallium zinc oxide (IGZO), or indium gallium silicon oxide (IGSO). The first terminal of the transistor is in contact with a first electrode of the capacitor along the first direction. The capacitor comprises a dielectric structure extending along the first direction, the first electrode is on at least one surface of the dielectric structure, and the dielectric structure has a first end and a second end opposite to each other along the first direction. The first end of the dielectric structure is closer to the first terminal of the transistor than the second end of the dielectric structure, and the first end of the dielectric structure has a greater size than the second end of the dielectric structure along the second direction.

In some implementations, the array structure comprises an isolating region that is between transistors of two adjacent memory cells of the plurality of memory cells. The isolating region has a first end close to first terminals of the transistors and a second end close to second terminals of the transistors, and the first end has a smaller size than the second end.

In some implementations, the gate structure comprises a conductive film having an angled or curved end closer to the first terminal of the transistor than the second terminal of the transistor.

In some implementations, the capacitor further comprises a second electrode and a capacitor body between the first electrode and the second electrode. The first electrode encloses the dielectric structure, the capacitor body covers the first electrode, and the second electrode covers the capacitor body. The array structure comprises supporting structures extending along the second direction and being distributed along the first direction between the first electrode and the second electrode or between first electrodes of two adjacent capacitors.

In some implementations, the array structure further comprises a plurality of bit lines, and one of the plurality of bit lines is in contact with the second terminal of the transistor, and adjacent bit lines are isolated by a corresponding isolating region. The array structure is integrated in a first die, and the semiconductor device further comprises a second die. The first die comprises at least one conductive interconnection, through which the one of the plurality of bit lines is coupled to a control circuit in the second die. A surface of a cover layer over the plurality of bit lines in the first die is in contact with a surface of the control circuit in the second die. The plurality of bit lines is closer to the second die than the capacitor.

Another aspect of the present disclosure features a method including: forming first portions of capacitors of a semiconductor structure on a semiconductor substrate; forming transistors of the semiconductor structure on the first portions of the capacitors; removing the semiconductor substrate to expose at least partially the first portions of the capacitors; and forming second portions of the capacitors by at least partially in replacement of at least one of the sacrificial material or the dielectric structure between the first electrodes of the capacitors. A first portion of a capacitor comprises a first electrode and a dielectric structure. The first electrodes of the capacitors are spaced by a sacrificial material. A second portion of the capacitor comprises a second electrode and a capacitor body between the first electrode and the second electrode.

In some implementations, forming second portions of the capacitors by at least partially in replacement of at least one of the sacrificial material or the dielectric structure between the first electrodes of the capacitors comprises at least partially removing the sacrificial material between the first electrodes of the capacitors, depositing a dielectric material on the first electrodes to form the capacitor bodies of the capacitors, and depositing at least one conductive film on the dielectric material to form the second electrodes of the capacitors.

In some implementations, forming the transistors of the semiconductor structure on the first portions of the capacitors comprises: forming transistor bodies of the transistors, the transistor bodies being coupled to the first electrodes of the capacitors, forming vertical gates of the transistors adjacent to the transistor bodies of the transistors, and forming an isolating region between two adjacent transistors. The isolating region has a first end close to the first electrodes of the capacitors and a second end opposite to the first end along a first direction, and the first end has a smaller size than the second end.

In some implementations, forming the transistors of the semiconductor structure on the first portions of the capacitors comprises: forming a conductive layer on the first portions of capacitors; annealing the conductive layer, such that a conductive material of the conductive layer reacts with the first electrodes of the capacitors to form a composite conductive material, forming a body on the conductive layer, and forming trenches extending through the layer of the composite conductive material and the body to form the first terminals of the transistors and the transistor bodies of the transistors, respectively.

In some implementations, the method further includes forming bit lines on second terminals of the transistors, forming at least conductive interconnect layer on the bit lines, and bonding the semiconductor structure with a control structure by bonding a surface of the at least conductive interconnect layer with a surface of control circuitry of the control structure.

In some implementations, forming the first portions of the capacitors of the semiconductor structure on the semiconductor substrate comprises: forming an array of holes through one or more dielectric layers on the semiconductor substrate, depositing a first conductive film on surfaces of the array of holes, and filling a dielectric material into the array of holes by depositing the dielectric material on the first conductive film to form dielectric structures of the capacitors. A dielectric structure of the dielectric structures has a first end and a second end opposite to each other. The first end is closer to a transistor than the second end, and the first end has a greater size than the second end. The dielectric layers are spaced by an isolating material.

Implementations of the present disclosure can provide one or more of the following technical advantages and/or benefits. For example, a capacitor in 3D memory devices can have an irregular (e.g., trapezoid) shape in cross-section views, where one capacitor end closer to first terminals of vertical transistors (e.g., source terminals) can be wider than the other end of the capacitor. Likewise, vertical transistor bodies can also have an irregular (e.g., trapezoid) shape in cross-section views, where one end in contact with first terminals of vertical transistors (e.g., source terminals) can be wider than the other end in contact with second terminals of vertical transistors (e.g., drain terminals). As such, when capacitors and transistors are vertically stacked, this configuration (e.g., “back-to-back trapezoid”) can enhance alignment precision between vertical transistor arrays and capacitor arrays, which is especially advantageous in advanced technologies featuring narrower pitches. Moreover, bit lines (BLs) can be formed by deposition and patterning of a conductive layer on top of second terminals of vertical transistors (e.g., drain terminals). Unlike buried BLs, this process does not require consumption of a part of vertical transistor bodies. Therefore, vertical transistor trenches are no longer required to be etched deeper than vertical transistor bodies. The feasibility of employing stop layers for BL trenches etches and vertical transistor etches can also ease the process difficulty. Furthermore, thermal budget is significantly improved because processes requiring high temperature (e.g., implantation during vertical transistors formation) are conducted before the deposition of high-k materials for capacitors. This sequence of options mitigates concerns about high temperatures potentially damaging the high-K materials.

The techniques can be applied to various types of semiconductor devices, volatile memory devices, such as DRAM memory devices, or non-volatile memory (NVM) devices, such as NAND flash memory, NOR flash memory, resistive random-access memory (RRAM), phase-change memory (PCM) such as phase-change random-access memory (PCRAM), spin-transfer torque (STT)-Magnetoresistive random-access memory (MRAM), among others. The techniques can also be applied to charge-trapping based memory devices, e.g., silicon-oxide-nitride-oxide-silicon (SONOS) memory devices, and floating-gate based memory devices. The techniques can be applied to three-dimensional (3D) memory devices. The techniques can be applied to various memory types, such as SLC (single-level cell) devices, MLC (multi-level cell) devices like 2-level cell devices, TLC (triple-level cell) devices, QLC (quad-level cell) devices, or PLC (penta-level cell) devices. Additionally or alternatively, the techniques can be applied to various types of devices and systems, such as secure digital (SD) cards, embedded multimedia cards (eMMC), or solid-state drives (SSDs), embedded systems, among others.

The details of one or more implementations of the subject matter of this present disclosure are set forth in the accompanying drawings and the description below. Other features, aspects, and advantages of the subject matter will become apparent from the description, the drawings, and the claims.

### BRIEF DESCRIPTION OF THE DRAWINGS

The accompanying drawings, which are incorporated herein and form a part of the present disclosure, illustrate aspects of the present disclosure and, together with the description, further serve to explain the principles of the present disclosure and to enable a person of ordinary skill in the pertinent art to make and use the present disclosure.

FIG. 1 illustrates a cross-sectional view of an example 3D semiconductor device with pillar capacitors.

FIG. 2A-2R illustrates cross-sectional views of example structures of an example 3D semiconductor structure at various stages of a fabrication process.

FIG. 3 illustrates a cross-sectional view of an example 3D semiconductor device with cup capacitors.

FIG. 4A illustrates an example of 3D vertical transistors with single-side gates.

FIG. 4B illustrates an example of 3D vertical transistors with dual-side gates.

FIG. 5 is a flow chart of an example process of forming a 3D semiconductor device.

FIG. 6 illustrates a block diagram of an example system having one or more semiconductor devices.

Like reference numbers and designations in the various drawings indicate like elements. It is also to be understood that the various exemplary implementations shown in the figures are merely illustrative representations and are not necessarily drawn to scale.

### DETAILED DESCRIPTION

Current vertical transistor techniques in Dynamic Random Access Memory (DRAM) involve a process of forming transistors on a front side of a substrate followed by forming capacitors vertically stacked over memory cell arrays. Subsequently, the substrate is bonded with a carrier wafer on its front side and then flipped over to form drain terminals and/or bit lines (BL) on the backside of the substrate after polishing away the substrate. Due to process limitations, buried BL are often used, which has disadvantages of high resistance and heightened parasitic coupling between BLs. Buried BL can further impact air gap formation between bit lines for isolation purposes. This is partially because buried bit lines are located below the surface of the substrate. In contrast, other bit line formation techniques can involve creating bit lines on the surface. This difference in depth can affect the ease with which air gaps can be formed. Additionally, when a first wafer, e.g., with DRAM array, is bonded with a second wafer, e.g., with complementary metal-oxide-semiconductor (CMOS) control circuitry, interconnect vias alignments are problematic because of the unwanted mechanical and thermal stress on the wafers arising from the two bonding process, e.g., bonding with a carrier wafer and bonding between DRAM wafer and CMOS wafer. This results in narrow contact landing process windows. Such issue becomes even severe with respective to more advantaged technologies where the pitch is further shrunken. Further, in some techniques, vertical transistor formation often involves implantation under high temperatures. However, high-k materials in capacitors may not perform well at extremely high temperatures. Because of this constraint, implantations for transistor terminals are carrier out prior to deposition of high-k materials. This increases process complexity in the manufacturing process, particularly when it comes to drain implantations, because drains can be at the bottom of transistor bodies, making it challenging for dopants to reach them effectively from the top of transistor bodies. An alternative way is to form drain terminals together with BLs after the substrate is thinned or polished away. However, at this stage capacitors are already formed with high-k materials, and thus there can be limited thermal budgets for drain formation.

Implementations of the present disclosure provide techniques for forming 3D memory devices, which can address the above issues. In some implementations, a 3D memory device is manufactured by the following steps: forming first portions of capacitors of a 3D memory device on a semiconductor substrate, the first portions of a capacitor including first electrodes, and first electrodes of the capacitors are spaced by a dielectric sacrificial material; forming transistors of the 3D memory device stacked over the first portions of the capacitors; removing the semiconductor substrate to expose at least partially the first portions of the capacitors; finally, forming second portions of the capacitors by replacing at least part of the sacrificial material between the first electrodes of the capacitors, a second portion of the capacitor comprising a second electrode and a dielectric capacitor body between the first electrode and the second electrode.

In some implementations, vertical transistor channels include at least one of polycrystalline silicon, indium gallium zinc oxide (IGZO), or indium gallium silicon oxide (IGSO) to enhance channel performance with high electron mobility. Further, capacitors can have an irregular (e.g., trapezoid) shape in cross-section views, where one capacitor end, that is closer to first terminals of vertical transistors, e.g., source terminals, can be wider than the other end of the capacitor. Likewise, vertical transistor bodies can also have an irregular (e.g., trapezoid) shape in cross-section views, where one end in contact with first terminals of vertical transistors, e.g., source terminals, is wider than the other end in contact with second terminals of vertical transistors, e.g., drain terminals. As such, when capacitors and transistors are vertically stacked together, this configuration (e.g., “back-to-back trapezoid”) can enhance alignment precision between vertical transistor arrays and capacitor arrays. Moreover, at least one conductive film in gate structures of vertical transistors can have an angled or curved end, e.g., an L-shape. A first portion of the L-shape gate extends along a lateral direction, e.g., BL direction, and a second portion of the L-shape gate extends along a vertical direction or at an inclined angle relative to the vertical direction. Additionally, the first portion of the L-shape, extending along BL direction, can be closer to first terminals of vertical transistors, e.g., source terminals, compared to second terminals, e.g., drain terminals.

In some implementations, BLs are formed by direct deposition and patterning of a conductive layer on top of second terminals of vertical transistors, e.g., drain terminals. Unlike buried BL, this process doesn't require consumption of a part of vertical transistor semiconductor bodies. As such, vertical transistor trenches are not required to be etched deeper than vertical transistor bodies. Furthermore, the feasibility of employing stop layers for BL trenches etches and vertical transistor etches also eases the process difficulty. Thermal budget is also significantly improved because processes requiring high temperature, e.g., implantation during vertical transistors processing, are conducted before the deposition of high-k materials for capacitors.

In some implementations, a carrier wafer is not used during the process of forming 3D memory devices. This can reduce or eliminate issues associated with a bonding process, such as alignment issue, surface contamination, thermal stress, mechanical stress, or wafer bowing, etc. With reduced thermal or mechanical stress, when a first wafer, e.g., DRAM array wafer, is bonded with a second wafer, e.g., CMOS control circuitry wafer, interconnect vias alignments are significantly improved. This enlarged contact landing process windows is especially advantageous in cutting-edge technologies where the pitch is further reduced.

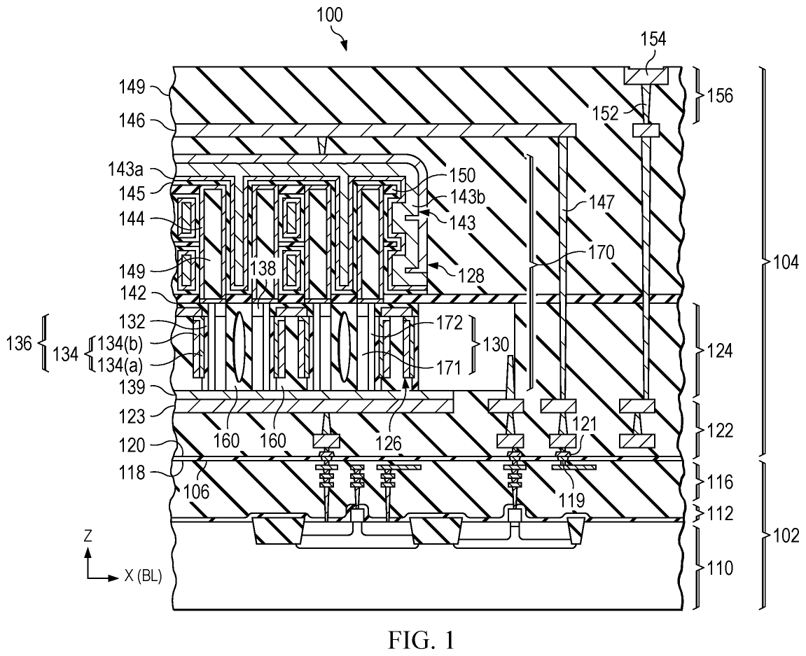

FIG. 1 illustrates a side view of a cross-section of an example 3D semiconductor device 100. The 3D semiconductor device 100 can be a 3D dynamic random-access memory (DRAM). It is understood that FIG. 1 is for illustrative purposes only and may not necessarily reflect the actual device structure (e.g., interconnections) in practice. In some implementations, the 3D semiconductor device 100 is a bonded chip including a first semiconductor structure 102 and a second semiconductor structure 104 stacked over the first semiconductor structure 102. The first and second semiconductor structures 102 and 104 can be jointed at bonding interface 106 therebetween.

As shown in FIG. 1, the first semiconductor structure 102 can include a substrate 110, which can include silicon (e.g., single crystalline silicon, c-Si), SiGe, GaAs, Ge, SOI, or any other suitable materials. The first semiconductor structure 102 can include peripheral circuits 112 on the substrate 110. In some implementations, the peripheral circuits 112 include a plurality of transistors (e.g., planar transistors and/or 3D transistors). Trench isolations (e.g., shallow trench isolations (STIs)) and doped regions (e.g., wells, sources, and drains of transistors) can be formed on or in the substrate 110 as well. In some examples, the peripheral circuits 112 are formed using complementary metal-oxide-semiconductor (CMOS) technology, and the first semiconductor structure 102 can be also formed on a semiconductor die that can be referred to as a control die or a CMOS die.

In some implementations, the first semiconductor structure 102 further includes an interconnect layer 116 above the peripheral circuits 112 to transfer electrical signals to and from the peripheral circuits 112. The interconnect layer 116 can include a plurality of interconnects (also referred to herein as “contacts”), including lateral interconnect lines and VIA contacts. The interconnect layer 116 can further include one or more interlay dielectric (ILD) layers in which the interconnect lines and via contacts can form. That is, the interconnect layer 116 can include interconnect lines and via contacts in multiple ILD layers. In some implementations, peripheral circuits 112 are coupled to one another through the interconnects in the interconnect layer 116. The interconnects in interconnect layer 116 can include conductive materials including, but not limited to, W, Co, Cu, Al, doped silicon, silicides, or any combination thereof. The ILD layers can be formed with dielectric materials including, but not limited to, silicon oxide, silicon nitride, silicon oxynitride, low-k dielectrics, or any combination thereof.

As shown in FIG. 1, the first semiconductor structure 102 has a front side and a back side, and the first semiconductor structure 102 can further include a bonding layer 118 at the back side at the bonding interface 106 and above the interconnect layer 116 and the peripheral circuits 112. The bonding layer 118 can include a plurality of bonding contacts 119 and dielectrics electrically isolating the bonding contacts 119. The bonding contacts 119 can include conductive materials, such as Cu. The remaining area of the bonding layer 118 can be formed with dielectric materials, such as silicon oxide. The bonding contacts 119 and surrounding dielectrics in the bonding layer 118 can be used for hybrid bonding. Similarly, as shown in FIG. 1, the second semiconductor structure 104 can also include a bonding layer 120 at the bonding interface 106 and above the bonding layer 118 of the first semiconductor structure 102. The bonding layer 120 can include a plurality of bonding contacts 121 and dielectrics electrically isolating the bonding contacts 121. The bonding contacts 121 can include conductive materials, such as Cu. The remaining area of the bonding layer 120 can be formed with dielectric materials, such as silicon oxide. The bonding contacts 121 and surrounding dielectrics in the bonding layer 120 can be used for hybrid bonding. The bonding contacts 121 can be in contact with the bonding contacts 119 at the bonding interface 106. In some implementations, the bonding layer 120 includes a dielectric layer opposing memory cells (e.g., DRAM cells) 124 with a bit line 123 positioned between the dielectric layer and the memory cells 124, as shown in FIG. 1. The dielectric layer can include the bonding interface 106 having the bonding contacts 121.

The second semiconductor structure 104 can be bonded on top of the first semiconductor structure 102 in a face-to-face manner at the bonding interface 106. In some implementations, the bonding interface 106 is disposed between the bonding layers 120 and 118 as a result of hybrid bonding (also known as “metal/dielectric hybrid bonding”), which is a direct bonding technology (e.g., forming bonding between surfaces without using intermediate layers, such as solder or adhesives) and can obtain metal-metal bonding and dielectric-dielectric bonding simultaneously. In some implementations, the bonding interface 106 is the place at which bonding layers 120 and 118 are met and bonded. In some examples, the bonding interface 106 can be a layer with a certain thickness that includes the top surface of the bonding layer 118 of the first semiconductor structure 102 and the bottom surface of the bonding layer 120 of the second semiconductor structure 104.

In some implementations, the second semiconductor structure 104 further includes an interconnect layer 122 including bit lines 123 above the bonding layer 120 to transfer electrical signals. The interconnect layer 122 can include a plurality of interconnects, such as mid end of line (MEOL) interconnects and back end of line (BEOL) interconnects. In some implementations, the interconnects in interconnect layer 122 also include local interconnects, such as the bit lines 123 and word line contacts (not shown). The interconnect layer 122 can further include one or more ILD layers in which the interconnect lines and via contacts can form. The interconnects in the interconnect layer 122 can include conductive materials including, but not limited to, W, Co, Cu, Al, doped silicon, silicides, or any combination thereof. The ILD layers can be formed with dielectric materials including, but not limited to, silicon oxide, silicon nitride, silicon oxynitride, low-k dielectrics, or any combination thereof.

In some implementations, the peripheral circuits 112 include a word line driver/row decoder coupled to the word line contacts in the interconnect layer 122 through the bonding contacts 121 and 119 in the bonding layers 120 and 118 and the interconnect layer 116. In some implementations, the peripheral circuits 112 include a bit line driver/column decoder coupled to the bit lines 123 and bit line contacts in the interconnect layer 122 through the bonding contacts 121 and 119 in the bonding layers 120 and 118 and the interconnect layer 116. In some implementations, the bit line 123 is a metal bit line, as opposed to semiconductor bit lines (e.g., doped silicon bit lines). For example, the bit line 123 may include W, Co, Cu, Al, or any other suitable metals having higher conductivities than doped silicon. In some implementations, the bit line contact is an ohmic contact as opposed to a Schottky contact.

In some implementations, the bit lines 123 are made of conductive materials, e.g., W, Co, Cu, Al, or anything combination thereof. In some implementations, the bit lines 123 are made of composite conductive material, including without limitations WSi, CoSi, CuSi, AlSi, or any other suitable metal silicides having higher conductivities than doped silicon.

In some implementations, the second semiconductor structure 104 includes a DRAM device in which memory cells are provided in the form of an array of DRAM cells 124 above the interconnect layer 122 and the bonding layer 120. That is, the interconnect layer 122 including the bit lines 123 can be disposed between bonding layer 120 and array of DRAM cells 124. A bit line 123 in the interconnect layer 122 can be coupled to a string of DRAM cells 124. In some implementations, the second semiconductor structure 104 is formed on a semiconductor die and can be referred to as array die.

In some implementations, a semiconductor device can include multiple array dies (e.g., the second semiconductor structure 104) and a CMOS die (e.g., the first semiconductor structure 102). The multiple array dies and the CMOS die can be stacked and bonded together. The CMOS die can be respectively coupled to each of the multiple array dies, and can respectively drive each of the multiple array dies to operate in the similar manner as the semiconductor device. The semiconductor device can be any suitable device. In some examples, the semiconductor device includes at least a first wafer and a second wafer bonded face to face. The array die can be disposed with other array dies on the first wafer, and the CMOS die can be disposed with other CMOS dies on the second wafer. The first wafer and the second wafer can be bonded together, thus the array dies on the first wafer can be bonded with corresponding CMOS dies on the second wafer. In some examples, the semiconductor device is a chip with at least the array die and the CMOS die bonded together. In an example, the chip is diced from wafers that are bonded together. In another example, the semiconductor device is a semiconductor package that includes one or more semiconductor chips assembled on a package substrate.

Each DRAM cell 124 can include a vertical transistor 126 and a capacitor 128 coupled to the vertical transistor 126. DRAM cell 124 can be a 1T1C cell consisting of one transistor and one capacitor. It is understood that DRAM cell 124 may be of any suitable configurations, such as 2T1C cell, 3T1C cell, etc. The vertical transistor 126 can be a MOSFET used to switch a respective DRAM cell 124. In some implementations, the vertical transistor 126 includes a transistortransistor body 130 (the active region in which a channel can form) extending vertically (in the z-direction), and a gate structure 136 in contact with one side of transistor body 130. In a single-gate vertical transistor, the transistor body 130 can have a cuboid shape or a cylinder shape, and the gate structure 136 can abut a single side of transistor body 130 in a plane view, e.g., as shown in FIG. 1. In some implementations, the gate structure 136 includes a gate electrode 134 and a gate dielectric 132 laterally between the gate electrode 134 and the transistor body 130 in a bit line direction (e.g., in the X direction). In some implementations, the gate dielectric 132 abuts one side of the transistor body 130, and the gate electrode 134 abuts the gate dielectric 132.

In some implementations, the gate electrode 134 includes multiple conductive layers, such as a W layer over a TiN layer. As illustrated in FIG. 1, the gate electrode 134 includes two layers, first gate electrode layer 134(a) (e.g., TiN) and second gate electrode layer 134(b) (e.g., W). The first gate electrode layer 134(a) can have an angled or curved end, e.g., a L-shape in X-Z plane view. The L-shaped gate electrode 134(a) includes two portions: a first portion extends along Z axis or along an inclined angle relative to the Z axis and a second portion extends along X axis. In addition, the second portion of gate electrode 134(a), which extends along x axis, is closer to first terminals 138 than second terminals 139.

It is understood that the structure of configuration of a gate structure 136 is not limited to the example in FIG. 1 and may include any suitable structure and configuration, such as a single-side gate structure, a dual-side gate structure, a triple-side gate structure, or a gate-all-around (GAA) structure.

As shown in FIG. 1, in some implementations, the transistor body 130 has two ends (the upper end and lower end in FIG. 1) in the vertical direction (the z-direction), and at least one end (e.g., the lower end) extends beyond gate dielectric 132 in the vertical direction (the z-direction) into the ILD layers (not shown). In some implementations, one end (e.g., the upper end) of the transistor body 130 is flush with the respective end (e.g., the upper end) of the gate dielectric 132. In some implementations, both ends (the upper end and lower end) of the transistor body 130 extend beyond the gate electrode 134, respectively, in the vertical direction (the z-direction) into ILD layers (not shown). That is, the transistor body 130 can have a larger vertical dimension (e.g., the depth) than that of the gate electrode 134 (e.g., in the z-direction), and neither the upper end nor the lower end of transistor body 130 is flush with the respective end of the gate electrode 134. Thus, short circuits between the bit lines 123 and the word lines/gate electrodes 134 or between the word lines/gate electrodes 134 and the capacitors 128 can be avoided. The vertical transistor 126 can further include a first terminal 138 and a second terminal 139, i.e. a source and a drain, disposed at the two ends (the upper end and lower end) of the transistor body 130, respectively, in the vertical direction (the z-direction). In some implementations, the first terminal 138 (e.g., at the upper end in FIG. 1) is coupled to the capacitor 128, and the second terminal 139 (e.g., at the lower end in FIG. 1) is coupled to the bit line 123. That is, the vertical transistor 126 can have a first terminal in the positive z-direction and a second terminal opposite the first terminal in the negative z-direction, as shown in FIG. 1.

In some implementations, the transistor body 130 includes semiconductor materials, such as single crystalline silicon, polysilicon, amorphous silicon, Ge, indium gallium zinc oxide (IGZO), or indium gallium silicon oxide (IGSO), any other semiconductor materials, or any combinations thereof. Terminals 138 and 139 can be doped with N+ type dopants (e.g., Phosphorus (P) or Arsenic (As)) or P-type dopants (e.g., Boron (B) or Gallium (Ga)) at a desired doping level, or comprise Silicon Germanium (SiGe).

In some implementations, the transistor body 130 includes a first body 171 and a second body 172 that are laterally in contact with each other. In some implementations, the second body 172 has a higher electron mobility than the first body 171, and the second body 172 is disposed laterally between the first body 171 and the gate dielectric 132 along X direction (e.g., the BL direction).

In some implementations, a silicide layer, such as a metal silicide layer, is formed between the second terminal 139 of the vertical transistor 126 and the bit line 123 as the bit line contact or between the first terminal 138 of the vertical transistor 126 and the first electrode of the capacitor 128 as capacitor contact 142 to reduce the contact resistance. In some implementations, gate dielectric 132 includes dielectric materials, such as silicon oxide, silicon nitride, or high-k dielectrics including, but not limited to, Al2O3, HfO2, Ta2O5, ZrO2, TiO2, or any combination thereof. In some implementations, gate electrode 134 includes a conductive material including, but not limited to W, Co, Cu, Al, TiN, TaN, polysilicon, silicide, or any combination thereof. In some implementations, the gate electrode 134 includes multiple conductive layers, such as a W layer over a TiN layer. In one example, the gate structure 136 may be a “gate oxide/gate poly” gate in which the gate dielectric 132 includes silicon oxide and gate electrode 134 includes doped polysilicon. In another example, gate structure 136 may be an HKMG in which gate dielectric 132 includes a high-k dielectric and gate electrode 134 includes a metal. High-k materials can include any material with a dielectric constant higher than or equal to a threshold value (e.g., 3.9).

As described above, since the gate electrode 134 may be part of a word line or extend in the word line direction (e.g., the Y direction) as a word line, the second semiconductor structure 104 of the 3D semiconductor device 100 can also include a plurality of word lines each extending in the word line direction. Each word line 134 can be coupled to a row of DRAM cells 124. That is, the bit line 123 and the word line 134 can extend in two perpendicular lateral directions, and the transistor body 130 of the vertical transistor 126 can extend in the vertical direction perpendicular to the two lateral directions in which the bit line 123 and the word line 134 extend. Word lines 134 are in contact with word line contacts (not shown). In some implementations, the word lines 134 include conductive materials including, but not limited to W, Co, Cu, Al, TiN, TaN, polysilicon, silicides, or any combination thereof. In some implementations, the word line 134 includes multiple conductive layers, such as a W layer over a TiN layer, as shown in FIG. 1.

In some implementations, as shown in FIG. 1, the vertical transistor 126 extends vertically through and contacts the word lines 134, and the second terminal 139 of vertical transistor 126 at the lower end thereof is in contact with the bit line 123 (or bit line contact if any). Accordingly, the word lines 134 and the bit lines 123 can be disposed in different planes in the vertical direction due to the vertical arrangement of vertical transistor 126, which simplifies the routing of the word lines 134 and the bit lines 123. In some implementations, the bit lines 123 are disposed vertically between the bonding layer 120 and the word lines 134, and the word lines 134 are disposed vertically between the bit lines 123 and the capacitors 128. The word lines 134 can be coupled to the peripheral circuits 112 in the first semiconductor structure 102 through word line contacts (not shown) in the interconnect layer 122, the bonding contacts 121 and 119 in the bonding layers 120 and 118, and the interconnects in the interconnect layer 116. Similarly, the bit lines 123 in the interconnect layer 122 can be coupled to the peripheral circuits 112 in the first semiconductor structure 102 through the bonding contacts 121 and 119 in the bonding layers 120 and 118 and the interconnects in the interconnect layer 116.

In some implementations, the vertical transistors 126 can be arranged in a mirror-symmetric manner to increase the density of DRAM cells 124 in the bit line direction (the X direction). As shown in FIG. 1, two adjacent vertical transistors 126 in the bit line direction are mirror-symmetric to one another with respect to a trench isolating region 160. That is, the second semiconductor structure 104 can include a plurality of trench isolating regions 160 each extending in the word line direction (the Y direction) in parallel with word lines 134 and disposed between transistor bodies 130 of two adjacent rows of the vertical transistors 126. In some implementations, the rows of vertical transistors 126 separated by the trench isolating region 160 are mirror-symmetric to one another with respect to the trench isolating region 160. The trench isolating region 160 can be formed with dielectric materials including, but not limited to, silicon oxide, silicon nitride, silicon oxynitride, low-k dielectrics, or any combination thereof. It is understood that the trench isolating region 160 may include an air gap each disposed laterally between adjacent transistor bodies 130. Air gaps may be formed due to the relatively small pitches of vertical transistors 126 in the bit line direction (e.g., the X direction). On the other hand, the relatively large dielectric constant of air in air gaps (e.g., about 4 times of the dielectric constant of silicon oxide) can improve the insulation effect between vertical transistors 126 (and rows of DRAM cells 124) compared with some dielectrics (e.g., silicon oxide). Similarly, in some implementations, air gaps are formed laterally between word lines/gate electrodes 134 in the bit line direction as well (not shown), depending on the pitches of word lines/gate electrodes 134 in the bit line direction. In some implementations, instead of having the air gaps in the trench isolating region 160, a conductive material (e.g., metal such as W) is filled in the trench isolating region 160 and surrounded by the dielectric materials. As described with further details below, the conductive material in the trench isolating region 160 can be coupled out from the back side of the second semiconductor structure 104.

As shown in FIG. 1, in some implementations, a capacitor 128 includes a first electrode 144 above and coupled to the first terminal 138 of vertical transistor 126, e.g., the upper end of the transistor body 130, via a capacitor contact 142. In some implementations, the capacitor contact 142 is an ohmic contact, such as a metal silicide contact, as opposed to a Schottky contact. For example, the capacitor contact 142 may include metal silicides, such as WSi, CoSi, CuSi, AlSi, or any other suitable metal silicides having higher conductivities than doped silicon.

In some implementations, the capacitor 142 includes a dielectric structure 149 which can have a pillar shape. The first electrode 144 covers at least one surface of the dielectric structure 149. In some implementations, the bottom portion of the first electrode 144 is coupled to a first terminal 138 of a corresponding vertical transistor 126 via an ohmic contact (e.g., the capacitor contact 142 made of a metal silicide material). A capacitor body 145 including a dielectric material (e.g., a high-k material) can be deposited on at least part of surfaces of the first electrode 144 followed by the deposition of a second electrode 143. In other words, the capacitor body 145 is between the first electrode 144 and the second electrode 143, where the capacitor body 145 at least partially covers the first electrode 144 and the second electrode 143 at least partially covers the capacitor body 145. The second electrode 143 can include one or more metallic layers that are stacked together. In some examples, e.g., as illustrated in FIG. 1, the second electrode 143 is formed by depositing a first metallic layer 143a (e.g., TiN) on surface of the capacitor body 145 and a second metallic layer 143b (e.g., SiGe) on the first metallic layer 143a. One or more supporting structures 150 can be extending along X axis and distributed between the first electrodes 144 and the second electrodes 143, and/or between first electrodes 144 of two adjacent capacitors 128, e.g., as illustrated in FIG. 1.

In some implementations, each first electrode 144 is coupled to the first terminal 138 of a respective vertical transistor 126 in the same DRAM cell, while all second electrodes are coupled to a common plate 146 coupled to the ground, e.g., a common ground. In some implementations, the capacitor 128 can have a first end in the negative z-direction and a second end opposite the first end in the positive z-direction (not shown). In some implementations, the first end of the capacitor 128 is coupled to the first terminal 138 of the vertical transistor 126 via an ohmic contact (e.g., the capacitor contact 142 made of a metal silicide material). As shown in FIG. 1, the second semiconductor structure 104 can further include a capacitor contact 147 (e.g., a conductor) in contact with a common plate 146 for coupling the capacitors 128 to the peripheral circuits 112 or to the ground directly. In some implementations, the capacitor contact 147 (e.g., a conductor) extends in the z-direction from the dielectric layer of the bonding layer 120 to couple to the second end of the capacitor 128 via the common plate 146, as shown in FIG. 1. In some implementation, the ILD layer in which the capacitors 128 are formed has the same dielectric material as the ILD layers into which the transistor body 130 extends, such as silicon oxide.

It is understood that the structure and configuration of a capacitor 128 are not limited to the example in FIG. 1 and may include any suitable structure and configuration, such as a pillar capacitor, a cup capacitor, a planar capacitor, a stack capacitor, a multi-fins capacitor, a cylinder capacitor, a trench capacitor, or a substrate-plate capacitor. In some implementations, the capacitor body 145 includes dielectric materials, such as silicon oxide, silicon nitride, or high-k dielectrics including, but not limited to, Al2O3, HfO2, Ta2O5, ZrO2, TiO2, or any combination thereof. It is understood that in some examples, a capacitor 128 may be a ferroelectric capacitor used in a FRAM cell, and the capacitor body 145 may be replaced by a ferroelectric layer having ferroelectric materials, such as PZT or SBT. In some implementations, the electrodes include conductive materials including, but not limited to W, Co, Cu, Al, TiN, TaN, polysilicon, silicides, or any combination thereof.

As shown in FIG. 1, vertical transistor 126 extends vertically through and contacts the word lines 134, the second terminal 139of vertical transistor 126 at the lower end thereof is in contact with the bit line 123, and the first terminal 138 of vertical transistor 126 at the upper end thereof is coupled to the capacitor 128. That is, the bit line 123 and the capacitor 128 can be disposed in different planes in the vertical direction and coupled to opposite ends of vertical transistor 126 of DRAM cell 124 in the vertical direction due to the vertical arrangement of vertical transistor 126. In some implementations, the bit line 123 and the capacitor 128 are disposed on opposite sides of the vertical transistor 126 in the vertical direction, which simplifies the routing of the bit lines 123 and reduces the coupling capacitance between the bit lines 123 and the capacitors 128 compared with DRAM cells in which the bit lines and capacitors are disposed on the same side of the planar transistors.

As shown in FIG. 1, in some implementations, the vertical transistors 126 are disposed vertically between the capacitors 128 and the bonding interface 106. That is, the vertical transistors 126 can be arranged closer to the peripheral circuits 112 of the first semiconductor structure 102 and the bonding interface 106 than the capacitors 128. Since the bit lines 123 and the capacitors 128 are coupled to opposite ends of the vertical transistors 126, the bit lines 123 (as part of the interconnect layer 122) are disposed vertically between the vertical transistors 126 and the bonding interface 106. As a result, the interconnect layer 122 including bit lines 123 can be arranged close to the bonding interface 106 to reduce the interconnect routing distance and complexity.

As shown in FIG. 1, the second semiconductor structure 104 can further include a pad-out interconnect layer 156 above the capacitors 128and the DRAM cells 124. The pad-out interconnect layer 156 can include interconnects, e.g., contact pads 154, in one or more ILD layers. The pad-out interconnect layer 156 and the interconnect layer 122 can be formed on opposite sides of the DRAM cells 124. The capacitors 128 can be disposed vertically between the vertical transistors 126 and the pad-out interconnect layer 156. In some implementations, the interconnects in pad-out interconnect layer 156 can transfer electrical signals between the 3D semiconductor device 100 and outside circuits, e.g., for pad-out purposes.

In some implementations, the second semiconductor structure 104 further includes one or more contacts 152 extending through part of the pad-out interconnect layer 156 to couple the pad-out interconnect layer 156 to the DRAM cells 124 and the interconnect layer 122. As a result, the peripheral circuits 112 can be coupled to the DRAM cells 124 through the interconnect layers 116 and 122 as well as the bonding layers 120 and 118, and the peripheral circuits 112 and the DRAM cells 124 can be coupled to outside circuits through contacts 152 and pad-out interconnect layer 156. Contact pads 154 and contacts 152 can include conductive materials including, but not limited to, W, Co, Cu, Al, silicides, or any combination thereof. In one example, the contact pad 154 may include Al, and the contact 152 may include W.

Although not shown, it is understood that the pad-out of 3D memory devices is not limited to from the second semiconductor structure 104 having DRAM cells 124 as shown in FIG. 1 and may be from the first semiconductor structure 102 having peripheral circuit 112. Although not shown, it is also understood that the air gaps between word lines 134 and/or between transistor bodies 130 may be partially or fully filled with dielectrics. Although not shown, it is further understood that more than one array of DRAM cells 124 may be stacked over one another to vertically scale up the number of DRAM cells 124.

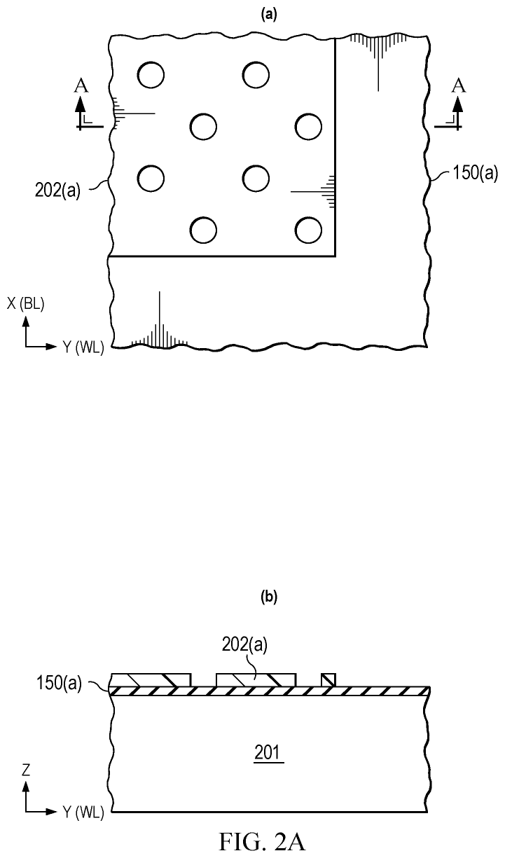

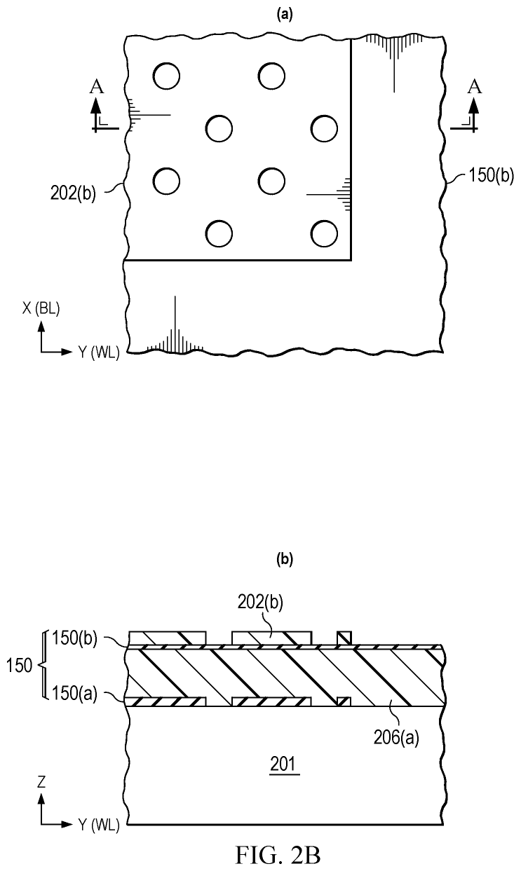

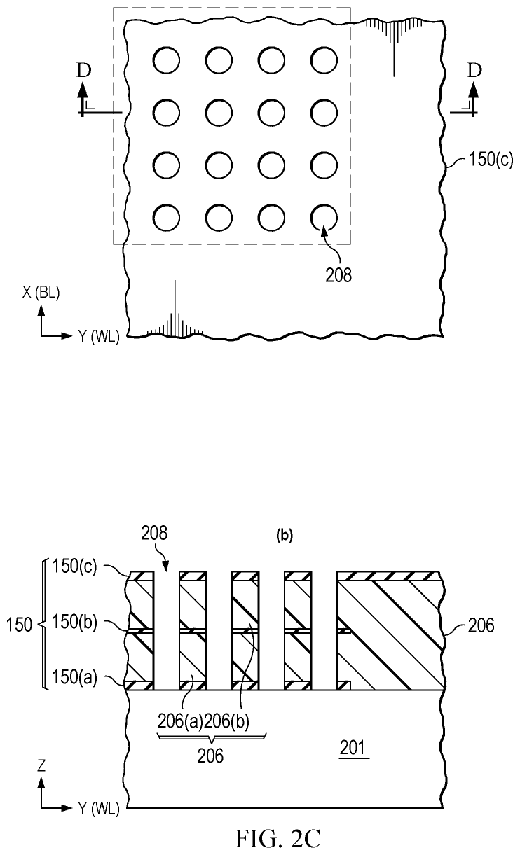

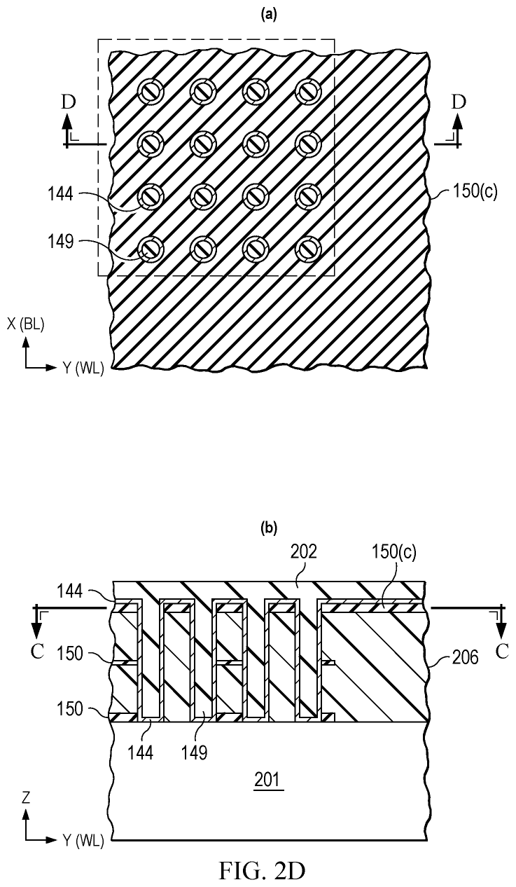

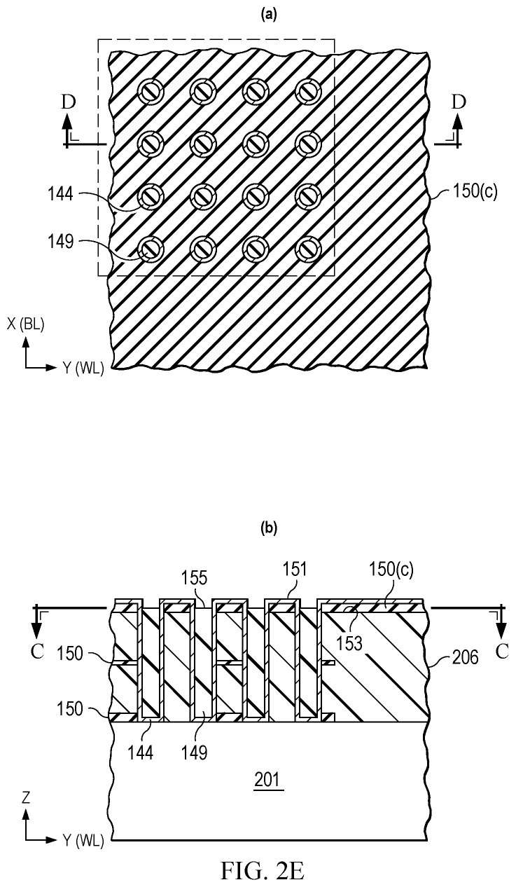

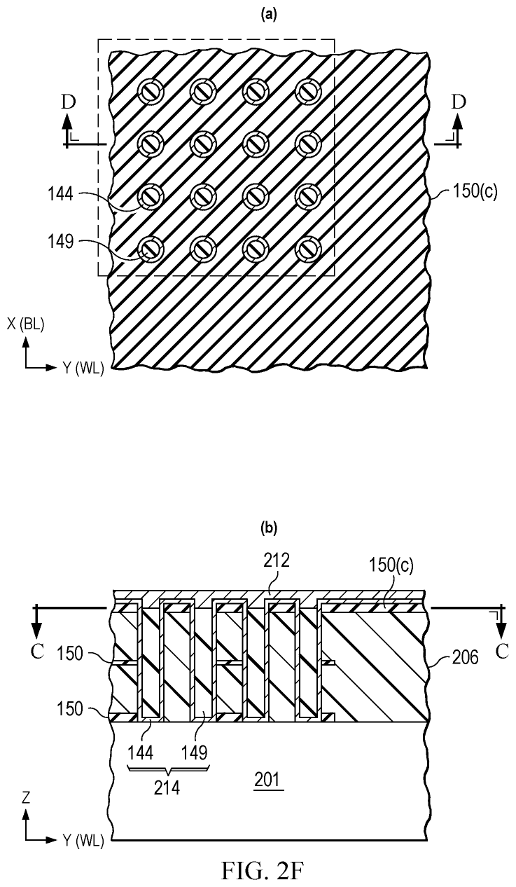

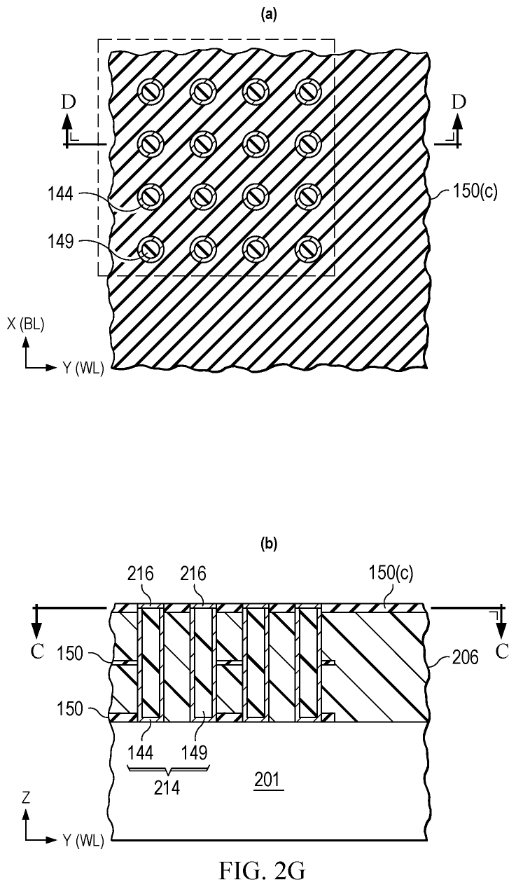

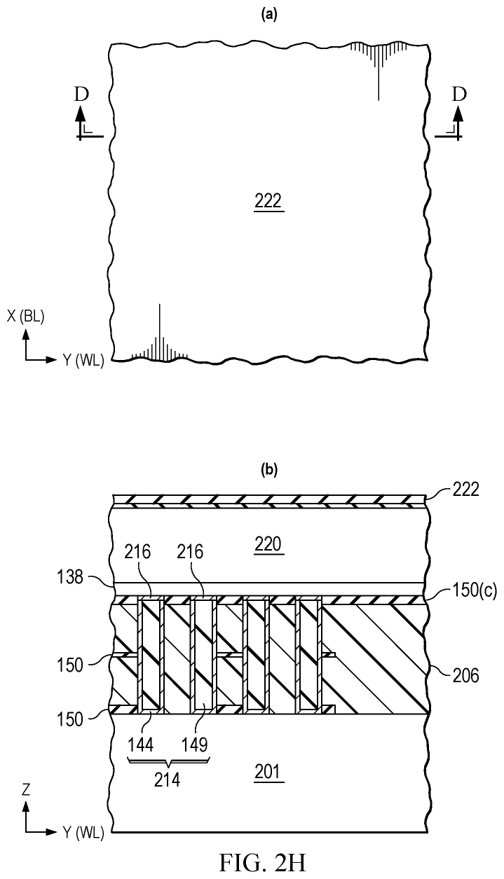

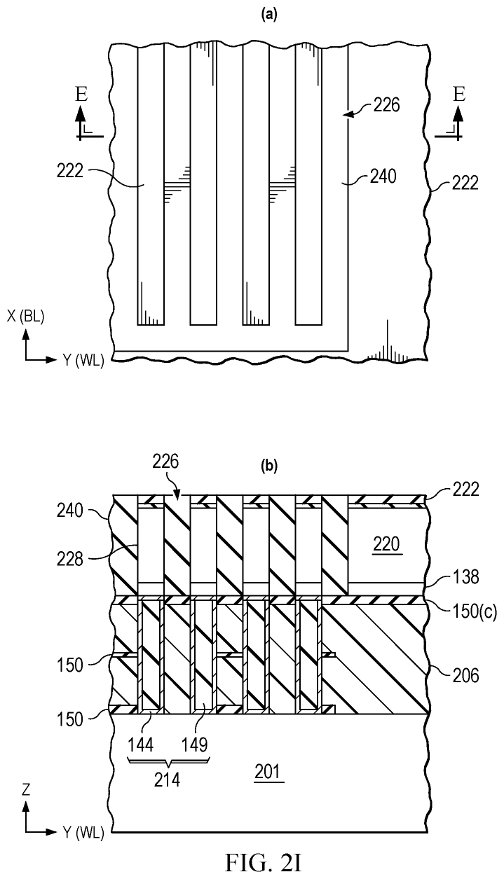

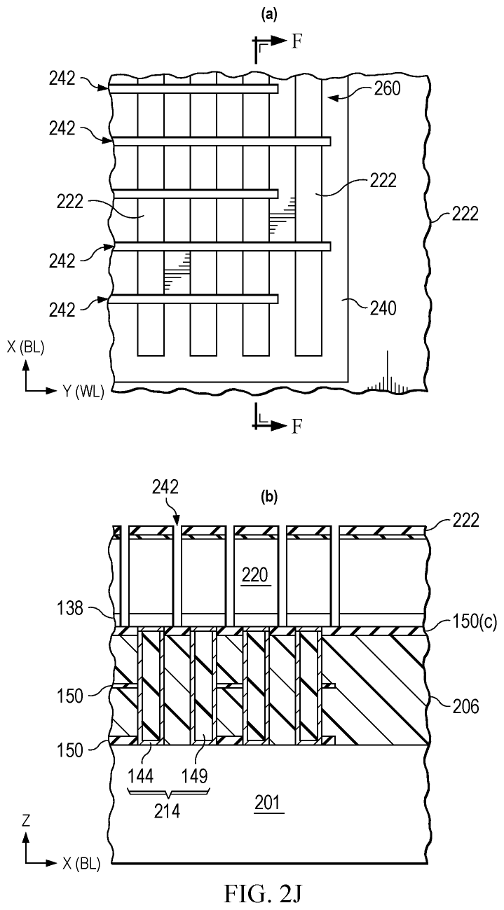

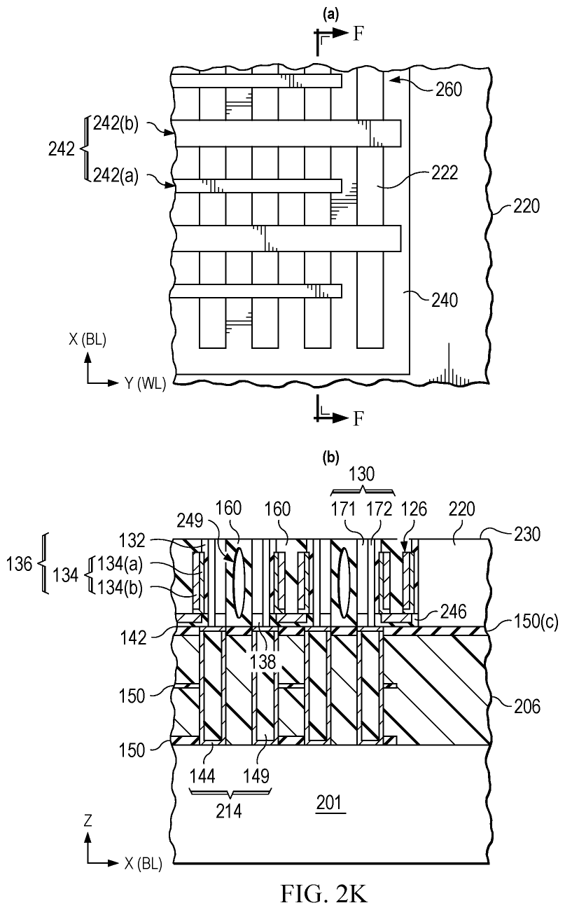

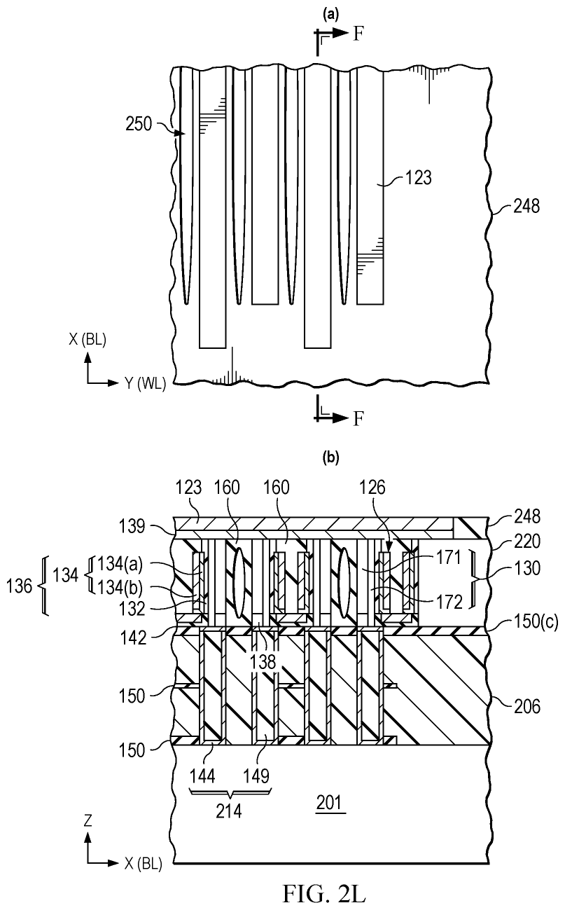

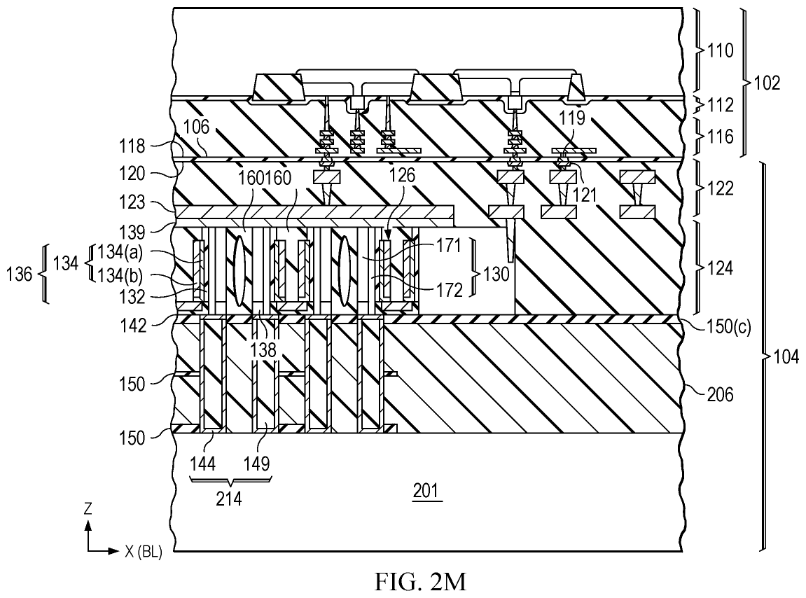

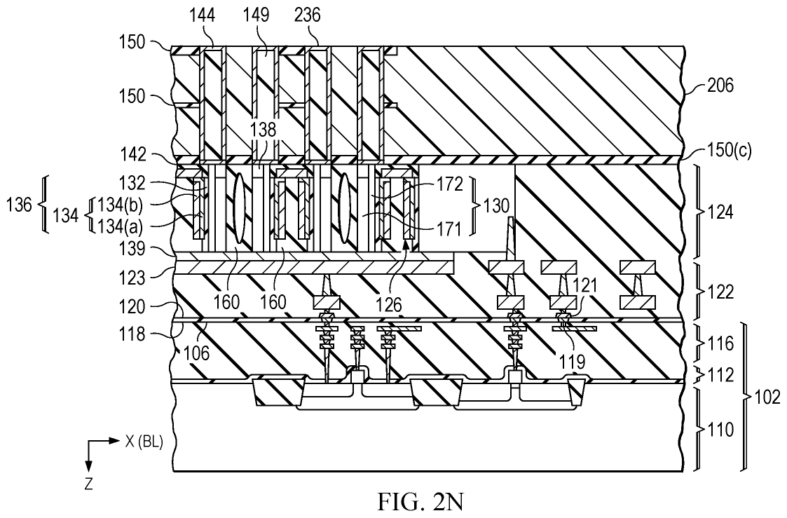

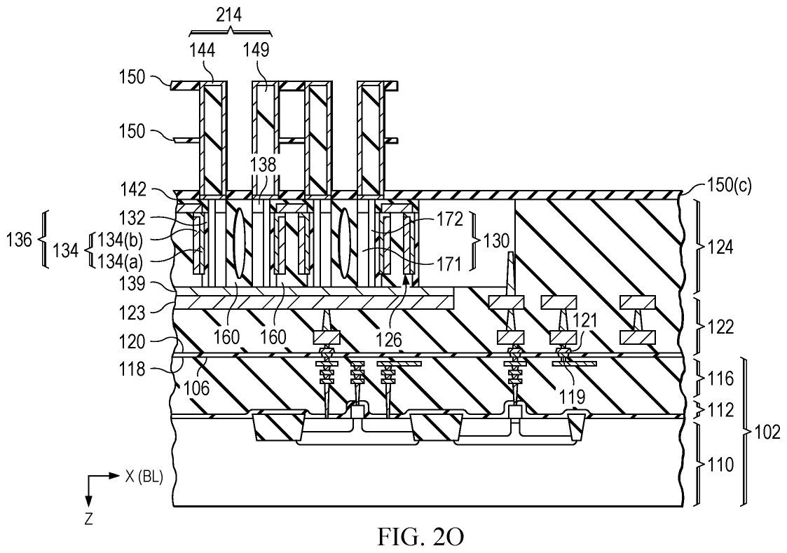

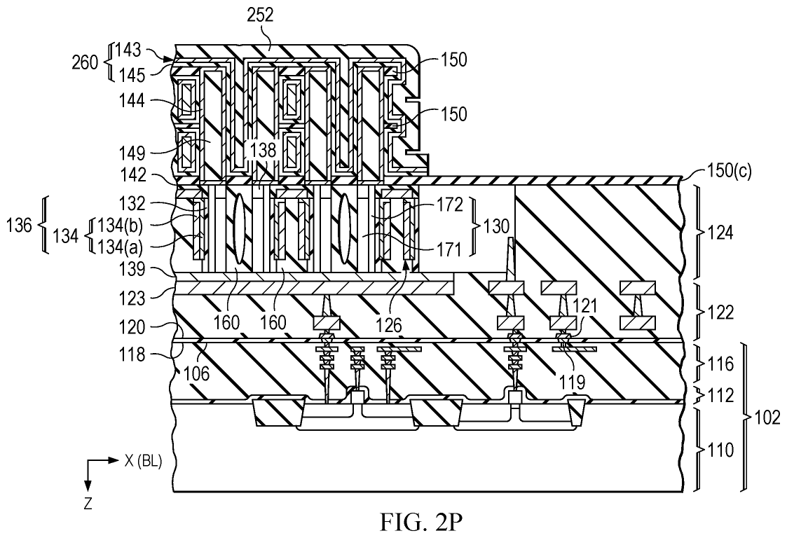

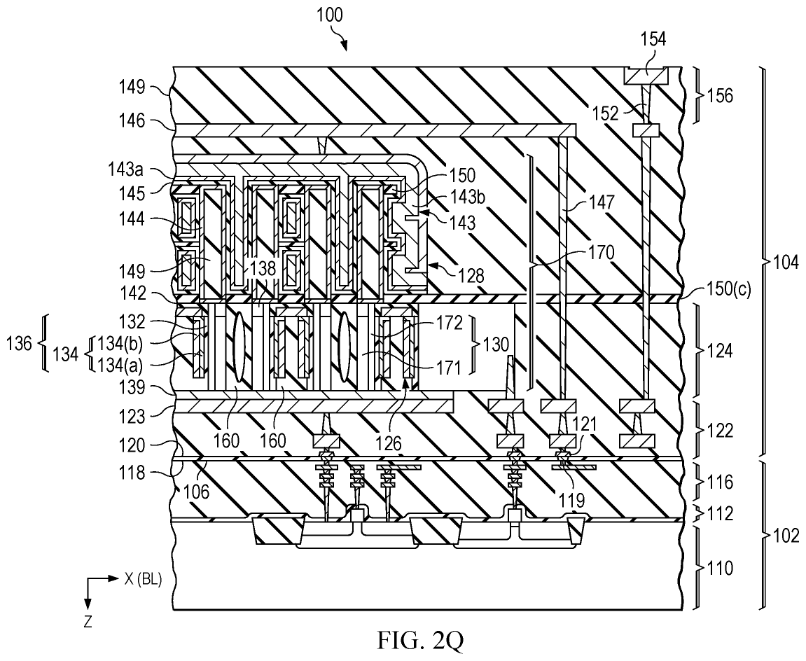

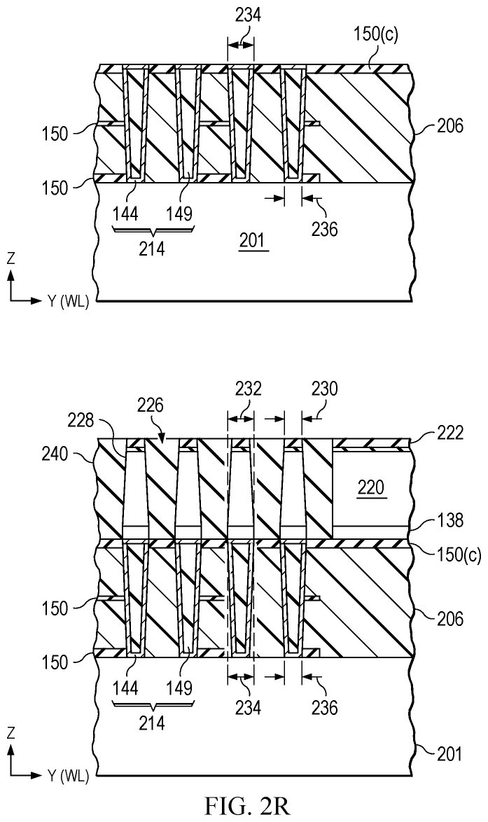

Although not shown in FIG. 1, it is understood that capacitors 128 can have an irregular shape (e.g., a trapezoid shape) in cross-section views, where one capacitor end, that is closer to first terminals 138 of vertical transistors 126 (e.g., source terminals) is wider than the other end of the capacitor, e.g., as illustrated below in FIG. 2R. Likewise, vertical transistor bodies 130 can also have an irregular shape (e.g., a trapezoid shape) in cross-section views, where one end in contact with first terminals 138 of vertical transistors 126 (e.g., source terminals) is wider than the other end in contact with second terminals 139 of vertical transistors 126 (e.g., drain terminals), e.g., as illustrated below in FIG. 2R. As such, when capacitors 128 and transistors 126 are vertically stacked together, this configuration (e.g., “back-to-back trapezoid”) can enhance alignment precision between vertical transistor arrays and capacitor arrays, which enables to form memory devices with narrower pitches.

FIGS. 2A-2R show top views and/or cross-sectional views of structures of an example semiconductor device at various stages of a fabrication process. The semiconductor device can be same as, or similar to, the semiconductor device 100 of FIG. 1, or a part of the 3D semiconductor device 100 of FIG. 1, or a structure at an intermediate fabrication process of the 3D semiconductor device 100 of FIG. 1. For illustration purposes, each of FIGS. 2A-2L includes cross-sectional views of a corresponding structure in diagrams (a) and (b), respectively. Diagram (a) shows a top view of the corresponding structure in X-Y plane, while diagram (b) shows a cross-sectional view of Y-Z plane for each of FIGS. 2A-2I, or a cross-sectional view of X-Z plane for each of FIGS. 2J-2L. FIGS. 2M-2Q have only one diagram which shows cross-sectional views of X-Z plane. FIG. 2R shows cross-sectional views of Y-Z plane. Y can represent a direction along which word lines (WLs) extend, e.g., WL direction, X can represent a direction along which bit lines (BLs) extend, e.g., BL direction, Z is a vertical direction along which capacitors 128 and memory cells 124 are stacked together.

FIGS. 2A-2G illustrate an example process of forming first portions of capacitor cell 214 on a substrate 201. The capacitor cell 214 can be same as, or similar to, the capacitor 128 of FIG. 1.

FIG. 2A diagram (a) illustrates the top view of X-Y plane, while FIG. 2A diagram (b) is a cross-sectional view in Y-Z plane (e.g., in the A-A plane through hole or trenches arrays). The same drawing layer is arranged in FIGS. 2B-2C as well.

As illustrated in FIG. 2A, a first supporting structure 150(a) is deposited on top of a substrate 201. Subsequently, a first layer of patterned photoresist 202(a) is formed on top of the first supporting structure 150(a) along Z-axis. A lithography process is employed to pattern the photo resist layer 150(a). The photo resist pattern can be an array of holes which extends along z-axis to expose at least part of the top surface of the underlying first supporting structure 150(a). In some implementations, the first supporting structure 150(a) includes dielectric materials, including, but not limited to, SiN, SiCN, or any combination thereof. The first supporting structure 150(a) can be deposited using one or more thin film deposition processes, including, but not limited to, chemical vapor deposition (CVD), physical vapor deposition (PVD), atomic layer deposition (ALD), sputtering, or any combination thereof.

As illustrated in FIG. 2B diagram (b), the first supporting structure 150(a) is partially etched on top of substrate 201 and the first patterned photoresist 202(a) is removed after etching. The first patterned photoresist 202(a) is used to protect certain areas of supporting structure 150 so that unprotected area is etched through by etchants until the top surface of substrate 201 is exposed. This patterned supporting structure 150 can be used to support capacitor arrays formed later. In some implementations, one or more dry etching and/or wet etching process, including, but not limited to, reactive ion etching (RIE), plasma etching, hydrofluoric acid (HF) etching, or any combination thereof, are performed on substrate 201.

Subsequently, a first scarification layer 206(a) is deposited on top of the first supporting structure 150(a) and fills the trenches and/or holes thereof. In some implementations, the first sacrificial layer 206(a) comprises dielectric materials, including, but not limited to, silicon dioxide (SiO2), low-k dielectric, silicon nitride, silicon oxynitride, or any combination thereof. The first sacrificial layer 206(a) can be deposited using one or more thin deposition processes, including, but not limited to, chemical vapor deposition (CVD), physical vapor deposition (PVD), atomic layer deposition (ALD), sputtering, or any combination thereof.

Following the deposition of the first sacrificial layer 206(a), a second layer of supporting structure 150(b) is deposited on top of the first sacrificial layer 206(a). In some implementations, the second supporting structure 150(b) can comprise the same material as the first supporting structure 150(a). A second patterned photoresist 202(b) is then formed to protect certain area of the second supporting structure 150(b) from subsequent etching process (not shown here). In some implementations, the pattern of the second photoresist 202(b) has the same layout as the first patterned photoresist 202(a), as shown in the diagram (a) of FIGS. 2A and 2B.

As illustrated in FIG. 2C diagram (b), repeating some or all process steps in FIGS. 2A and 2B results in a second patterned supporting structure 150(b), a top patterned supporting structure 150(c) and a last sacrificial layer 206(b). In some implementations, the top patterned supporting structure 150(c) can have a different array pattern than the first and/or second supporting structure 150(a) & (b) (not shown). In some implementations, the top patterned supporting structure 150(c) can comprise the same material as the first and/or second supporting structure 150(a) & (b). In some examples, the third supporting structure 150(c) includes Silicon boron nitride (SiBN).

Subsequently, an array of capacitor trenches 208 are formed by etching through all layers of supporting structure 150 and sacrificial layers 206 along Z-axis until the top surface of substrate 201 is exposed, as shown in FIG. 2C diagram (b). In some implementations, a double patterning technique is employed to create smaller features and pitches for the array of capacitor trenches 208. In some implementations, one or more dry etching and/or wet etching process, including, but not limited to, reactive ion etching (RIE), plasma etching, hydrofluoric acid (HF) etching, or any combination thereof, are performed to form the capacitor trenches 208.

As illustrated in FIG. 2C diagram (b), multiple layers of patterned supporting structure 150 are stacked together along Z direction and isolated by sacrificial layers 206. For example, the first supporting structure 150(a) is separated from the second supporting structure 150(b) by the first sacrificial layer 206(a), while the second supporting structure 150(b) is separated from the top supporting structure 150(c) by the last sacrificial layer 206(b). Although FIG. 2C illustrates a total of 3 layers of supporting structures 150 and 2 sacrificial layers 206, it is understood that the supporting structure 150 can have one or more layers and sacrificial layer 206 can also have one or more layers. In the description below, top supporting structure 150(c) refers to the top layer of one or more supporting structure layers along positive Z-direction, not limited to the third supporting structure. In other words, if there is a total of one supporting structure, then top supporting structure 150(c) refers to that supporting structure; if there are a total of 5 supporting structure, then top supporting structure 150(c) refers to the fifth supporting structure that is stacked above the first 4 supporting structures along a positive Z-direction.

Further, although FIG. 2C diagram (b) shows all three supporting structures, e.g., 150(a) 150(b) and 150(c), have the identical array pattern, it is further understood that different layers of patterned supporting structure 150 can have different patterns, structure thicknesses, sizes, and/or materials, and be formed using the same or different process techniques.

FIG. 2D diagram (b) illustrates the cross-section view of the Y-Z plane, while FIG. 2D diagram (a) is a cross-sectional view in the X-Y plane (e.g., in the CC plane through the top supporting structure 150(c) and a row of dielectric structure 149).

Referring to FIG. 2D diagram (b), a first electrode 144 for capacitors is firstly deposited which covers at least part of inner surfaces of capacitor trenches 208, as well as at least part of a top surface of supporting structure 150. The thickness of the first capacitor electrode 144 is smaller than the radius of capacitor trenches 208. In other words, the first electrode 144 materials won't completely fill the capacitor trenches 208, and thus there are still some spaces remaining inside capacitor trenches 208 after the deposition of first capacitor electrode 144. In some implementations, an electrode material of the first capacitor electrode 144 includes, but not limited to, TiN, TaN, Al, W, Cu, Co, Cu, doped-polysilicon, silicides, or any combination thereof. In some implementations, the first capacitor electrode 144 is deposited by one or more thin film deposition processes including, but not limited to, Chemical Vapor Deposition (CVD), Physical vapor deposition (PVD), Atomic layer deposition (ALD), Metal-Organic Chemical Vapor Deposition (MOCVD), sputtering, electroplating, electroless plating, or any combination thereof.

A dielectric material is subsequently deposited into capacitor trenches 208 which completely or substantially fill the remaining spaces of capacitor trenches 208, forming a dielectric structure 149 for the purpose of supporting. Accordingly, as shown in FIG. 2D diagram (a), capacitor trenches 208 has a dielectric structure 149 in the trench center laterally surrounded by the first electrode 144. In some implementations, the dielectric structure 149 includes a dielectric material including, but not limited to, polysilicon, carbon, or any combination thereof. The dielectric structure 149 can be deposited by one or more thin film deposition processes including, but not limited to, CVD, PVD, ALD, MOCVD, sputtering, or any combination thereof. In some implementations, during the deposition of dielectric structure 149, a dielectric layer 202 is formed on top of the supporting structure 150, as illustrated in FIG. 2D diagram (b).

FIG. 2E diagram (a) illustrates a top view of the X-Y plane, while FIG. 2E diagram (b) is a cross-sectional view in Y-Z plane (e.g., in the D-D plane through a row of dielectric structure 149). The same drawing layer is arranged in FIGS. 2F-G as well.

As illustrated in FIGS. 2D diagram (b) and 2E diagram (b), the dielectric layer 202 is etched away and a top portion of dielectric structure 149 is also recessed by etching. Consequently, the top surface of recessed dielectric structure 149 after etching is lower than the top surface 151 of the first electrode 144 along Z-axis. In some implementations, the top surface of recessed dielectric structure 149 is flush with the top surface of last sacrificial layer 206(b). Although not shown in FIG. 2E, it is understood that the top surface 155 of recessed dielectric structure 149 can be higher or lower than the top surface 153 of sacrificial layer along Z-axis. In some implementations, etching and recess can involve one or more dry etching and/or wet etching process, including, but not limited to, reactive ion etching (RIE), plasma etching, hydrofluoric acid (HF) etching, or any combination thereof.

Referring to FIGS. 2E and 2F, a layer of conductive material, e.g., conductive film, is deposited to fill in the recessed space of dielectric structure 149 and form a uniform conductive layer 212 on top of the top supporting structure 150(c). The conductive layer 212 can include the same conductive material as the first electrode 144. Subsequently, a polishing process is performed to remove the conductive layer 212 such that the top surface of top supporting structure 150(c) is exposed, as shown in FIG. 2G diagram (b). Consequently, each dielectric structure 149 is enclosed by a first electrode 144, forming a first portion of capacitor cell 214. Further, each first portion of capacitor cell 214 is isolated by sacrificial layer 206 and supporting structure 150. In other words, there are no conductive communication channels between each first portion capacitor cell 214 at this stage. Although not shown in FIG. 2G, it is understood that top supporting structure 150(c) and top portion of first electrode 216 may be partially polished so that they become thinner after polish. In some implementations, the polishing process can include, but not limited to, chemical mechanical polishing (CMP), mechanical polishing, electrochemical polishing, ultrasonic polishing, or any combination thereof.

At this stage, first portions of capacitor cells 214 are finished. Although not shown in FIGS. 2A-2Q, first portions of capacitor cell 214 can have an irregular (e.g., trapezoid shape) in Y-Z plane. Referring to FIG. 2R diagram (a), a dielectric structure 149 has two ends: a first capacitor end 234 in the positive z direction and a second capacitor end 236 in the negative z direction, where the second capacitor end 236 is closer to a substrate 201 compared to the first capacitor end 234. As illustrated in FIG. 2R diagram (a), the first capacitor end 234 can be wider than the second capacitor end 236, forming a trapezoid shape in Y-Z plane, e.g., due to etching from the first capacitor end 234 to the second capacitor end 236. The greater first capacitor end 234 enables to increase an overlay window of the capacitor cell 214.

FIGS. 2H-2L illustrate an example process to form vertical transistors 126 and BLs 123 on top of the first portions of capacitor cell 214.

Referring to FIG. 2H, in some implementations, a layer of first terminal 138 is deposited followed by the deposition of a body 220. The first terminal 138 is used as one of two terminals for a vertical transistor 126 (See FIG. 1), e.g., source terminal, while body 220 is used to form a semiconductor body of the vertical transistor 126. In some implementations, the material for first terminal 138 can include, but not limited to, doped Si with N-type or P-type dopants, SiGe, GaAs, or any combination thereof. N-type dopants can include, but not limited to, phosphorus (P), arsenic (As), antimony (Sb), or any combination thereof. P-type dopants can include, but not limited to, boron (B), aluminum (Al), gallium (Ga), or any combination thereof. An annealing process can be performed to form a compositive conductive material, e.g., silicide, at the interface between first terminal 138 and first electrode 144. In some implementations, the body 220 includes, but not limited to, amorphous silicon, polysilicon, single crystal silicon, or any combination thereof. In some implementations, first terminal 138 and body 220 can be deposited by one or more thin film deposition processes including, but not limited to, CVD, PVD, ALD, MOCVD, molecular beam epitaxy (MBE), sputtering, or any combination thereof.

In some implementations, the first terminal 138 is part of the transistor channel material, e.g., Indium gallium zinc oxide (IGZO), as described below. One end of IGZO is coupled to the capacitor 128, while the other end of IGZO is coupled to the bit line 123. As such, a separate deposition for the first terminal material and/or its subsequent anneal process is not required.

On top of body 220, one or more layers of hard mask are deposited to protect selected area of body 220 in subsequent etching process, as shown in FIG. 2H diagram (b). In some implementations, a hard mask material include, but limited to, silicon nitride (Si3N4), silicon oxide (SiO2), silicon oxynitride, Silicon Carbide (SiC), or any combination thereof.

FIG. 2I diagram (a) illustrates a top view of the X-Y plane, while FIG. 2I diagram (b) is a cross-section view in the Y-Z plane (e.g., in the E-E plane through a row of body trenches).

As illustrated in FIG. 2I diagram (a), an array of body trenches 226 are formed. Each body trench 226 extends along the X direction (BL direction) and two adjacent body trenches 226 are distributed along Y direction (WL direction). The width of a body trench 226 in the X direction is shorter than the length of the body trench 226 in the Y direction. Body trenches 226 are etched vertically along Z direction until at least part of top supporting structure 150(c) is exposed. Each body trench 226 can have a same pitch, critical dimension (CD), or size, etc. In some implementations, the etching of body 220 to form body trenches 226 can involve one or more dry etching and/or wet etching process, including, but not limited to, reactive ion etching (RIE), plasma etching, hydrofluoric acid (HF) etching, sputtering etching, KOH Etching (Potassium Hydroxide), TMAH Etching (Tetramethylammonium Hydroxide), Buffered Oxide Etchant (BOE), Piranha Solution (H2SO4/H2O2), or any combination thereof.

An annealing process is subsequently conducted to form a thin layer of silicon oxide (not shown in FIG. 2I) along vertical sidewalls 228 of body trenches 226 to repair the exposed silicon surface. A dielectric filling material 240 is then deposited to fill in body trenches 226 followed by a polishing process to have a top surface of dielectric fillings 240 flush with a top surface of hard mask 222. The dielectric filling material240 can include a dielectric material including, but not limited to, silicon oxide, silicon nitride, silicon oxynitride, low-k dielectrics, or any combination thereof. The dielectric filling material 240 can be deposited by one or more thin film deposition processes including, but not limited to, CVD, PVD, ALD, sputtering, or any combination thereof. In some implementations, the polishing process includes, but not limited to, chemical mechanical polishing (CMP), mechanical polishing, electrochemical polishing, ultrasonic polishing, or any combination thereof.

Although not shown in FIG. 2I, it is understood that body trenches 226 and/or patterned body 220 can a trapezoid shape in Z-Y plane, e.g., due to etching from a top end to a bottom end. Referring to FIG. 2R diagram (b), patterned body 220 can have a first body end 230 in the positive z-direction and a second body end 232 opposite to the first body end 230 in the negative z-direction. The second body end 232 is closer to first terminals 138 compared to the first body end 230. In some implementations, the first body end 230 is narrower than the second body end 232 with a trapezoid shape. Correspondingly, body trenches 226 have an inverted trapezoid shape where the top end of body trenches 226 are wider than the bottom end of body trenches 226, where the bottom end of body trenches are closer to first terminals compared to top end of body trenches.

As noted above, first capacitor end 234 is wider than second capacitor end 236. The second body end 232 is coupled with the first capacitor end 234 via first terminals 138 and first electrodes 144. Because both second body ends 232 and first capacitor ends 234 are wider, this “back-to-back trapezoids” configuration facilitates overlay alignment between patterned body 220 and first portions of capacitor cell 214, e.g., benefiting advanced semiconductor process techniques with narrower pitches.

As illustrated in FIG. 2J, vertical gate (VG) trenches 242 are formed with each VG trench extending along WL line direction (Y-axis). The vertical gate trenches 242 are penetrating body 220 and dielectric fillings 240 along Z direction so that at least part of top surface of top supporting structure 150(c) is exposed at the bottom of VG trenches 242. In some implementations, the critical dimension (CD), such as the width and depth, and pitches between adjacent VG trenches 242 are the same. In some implementations, the VG trenches 242 can have different lengths along WL direction (see FIG. 2J diagram (a)). The trench etching can involve one or more dry etching and/or wet etching process, including, but not limited to, reactive ion etching (RIE), plasma etching, hydrofluoric acid (HF) etching, sputtering etching, KOH Etching (Potassium Hydroxide), TMAH Etching (Tetramethylammonium Hydroxide), Buffered Oxide Etchant (BOE), Piranha Solution (H2SO4/H2O2), or any combination thereof. In some implementations, a self-aligned double patterning (SADP) is employed to create finer and more densely packed trenches features with smaller pitches.

FIG. 2K diagram (a) illustrates a top view of the X-Y plane, while FIG. 2K diagram (b) is a cross-section view in the X-Z plane (e.g., in the F-F plane through a row of vertical transistors). The same drawing layer is arranged in FIG. 2L as well.

From FIG. 2I to FIG. 2K, multiple process sub-steps are involved to form vertical transistors 126. Although not illustrated in FIG. 2K, process sub-steps are described below.

At least some of VG trenches 242 are expanded along BL direction (X axis) so that the width of expanded VG trenches 242(b) along X-axis is wider than that of unexpanded trenches 242(a). As illustrated in FIG. 2K, the length of unexpanded VG trenches 242(a) along WL direction (Y axis) can be shorter than that of expanded VG trenches 242(b). In some implementations, although not shown in FIG. 2K, it is understood that the length of unexpanded VG trenches 242(a) along WL direction (Y axis) can be longer than or equal to that of expanded VG trenches 242(b). In some implementations, as shown in FIG. 2K diagram (a), unexpanded VG trenches 242(a) and expanded VG trenches 242(b) are interleaved such that there is an expanded VG trench 242(b) between two unexpanded VG trench 242(a) along BL direction (X axis). In some implementations, the expanding process can be achieved by etching, involving one or more dry etching and/or wet etching process, including, but not limited to, reactive ion etching (RIE), plasma etching, hydrofluoric acid (HF) etching, sputtering etching, KOH Etching (Potassium Hydroxide), TMAH Etching (Tetramethylammonium Hydroxide), Buffered Oxide Etchant (BOE), Piranha Solution (H2SO4/H2O2), or any combination thereof. After etching, at least a portion of the remaining body 220 can be used as first semiconductor bodies 171 to form vertical transistors 126.

A bottom dielectric material 246 is deposited into both expanded VG trenches 242(b) and unexpanded VG trenches 242(a) for isolation purpose, forming isolating regions 160. It is understood that depending on the pitches of the VG trenches 242, air gaps 249 may be formed in isolating region 160. In some implementations, the bottom dielectric material 246 can be formed with dielectric materials including, but not limited to, silicon oxide, silicon nitride, silicon oxynitride, low-k dielectrics, or any combination thereof. The bottom dielectric material 246 can be deposited by one or more thin film deposition processes including, but not limited to, CVD, PVD, ALD, MOCVD, molecular beam epitaxy (MBE), sputtering, or any combination thereof.

An etching process can be performed to etch the bottom dielectric material 246 down to a specified height above the top surface of top supporting structure 150(c). The remaining bottom dielectric material 246 after etching can be functioned as a gate spacer for isolation purpose. In some implementations, the etching process is conducted only in expanded VG trenches 242(b), while unexpanded VG trenches 242(a) remain unetched and can be protected by a hard mask during etch (hard mask not shown in FIG. 2K). In some implementations, the remaining height of bottom dielectric materials 246 along Z direction after etching can be at least 70 nm above the top surface of top supporting structure 150(c). The etching can involve one or more dry etching and/or wet etching process, including, but not limited to, reactive ion etching (RIE), plasma etching, hydrofluoric acid (HF) etching, sputtering etching, KOH Etching (Potassium Hydroxide), TMAH Etching (Tetramethylammonium Hydroxide), Buffered Oxide Etchant (BOE), Piranha Solution (H2SO4/H2O2), or any combination thereof.

A second body 172 can be deposited on sidewalls of VG trenches 242, laterally covering first body 171. The second body 172 can form transistor channels of vertical transistors 126 (see FIG. 2K diagram (b)). The second body 172 can be deposited either prior to or after the deposition of bottom dielectric materials 246. A transistor body 130 includes at least one portion of first body 171 and a second body 172. In some implementations, the second body 172 laterally covers both the first body 171 and at least part of first terminals 138. A material of the second body 172 can include, but not limited to, polycrystalline silicon, indium gallium zinc oxide (IGZO), or indium gallium silicon oxide (IGSO), or any combination thereof. The first body 171 can comprise a same material as the body 220, which includes, but not limited to, amorphous silicon, polysilicon, single crystal silicon, or any combination thereof. In some implementations, the second body 172 has a higher electron mobility than the first body 171. The second body 172 can be deposited by one or more thin film deposition processes including, but not limited to, CVD, PVD, ALD, MOCVD, MBE, sputtering, or any combination thereof.

In some implementations, the transistor channels of vertical transistors 126 are formed by annealing the polysilicon after the first body 171, e.g., polysilicon, is formed. Annealing can change the properties of a surface layer of the first body 171, making the surface layer suitable for use in transistor channels. This surface layer used for transistor channels can be the second body 172 in FIG. 2K diagram (b).

A gate dielectric 132 layer is deposited on sidewalls of VG trenches 242 to form gate oxide. As shown in FIG. 2K diagram (b), the gate dielectric 132 is in contact with and laterally covers at least part of the second body 172. In some implementations, the length of gate dielectric 132 along Z axis can be equal to or shorter than that of second body 172. In some implementations, the gate dielectric 132 includes a dielectric material, such as silicon oxide, silicon nitride, or high-k dielectrics including, but not limited to, Al2O3, HfO2, Ta2O5, ZrO2, TiO2, any material with a dielectric constant higher than or equal to 3.9, or any combination thereof. The gate dielectric 132 can be deposited by one or more thin film deposition processes including, but not limited to, CVD, PVD, ALD, MOCVD, MBE, sputtering, or any combination thereof.

A gate electrode 134 is deposited on surfaces, including sidewalls, of VG trenches 242 which laterally covers at least part of gate dielectric 132. In some implementations, gate electrode 134 includes a conductive material including, but not limited to W, Co, Cu, Al, TiN, TaN, polysilicon, silicide, or any combination thereof. In some implementations, the gate electrode 134 includes multiple conductive layers, such as a W layer over a TiN layer, as shown in FIG. 2K diagram (b), where the gate electrode 134 includes two layers, first gate electrode layer 134(a) (e.g., TiN) and second gate electrode layer 134(b) (e.g., W).

In some implementations, top end of gate electrodes 134 can be later recessed or etched so that the top end of gate electrode 134 is vertically lower than the top surface of the first body 171 along Z direction, where the “top” end of gate electrode 134 can be defined as the electrode end in the positive Z direction. In addition, the bottom end of gate electrode 134 can be in contact with the top surface of bottom dielectric materials 246, where the “bottom” end of gate electrode 134 is opposite to the top end along negative Z direction. As such, the length of gate electrode 134 along Z direction can be shorter than that of first body 171.

In some implementations, first gate electrode layer 134(a) can have an angled or curved end, e.g., a L-shape in X-Z plane view. As shown in FIG. 2K diagram (b), the L-shaped gate electrode 134(a) includes two portions: a first portion extends along Z axis or along an inclined angle relative to the Z axis and a second portion extends along X axis. In addition, the second portion of gate electrode 134(a), which extends along x axis, is closer to first terminals 138 than first body end 230. The two adjacent L-shaped gate electrodes 134 in the BL direction (X axis) can be mirror-symmetric to one another with respect to a trench isolating region 160. In other words, one L-shaped gate electrode 134 can have a portion extending along the positive-x direction, while its adjacent L-shaped gate electrode 134 can have a portion extending along the negative-x direction, forming a mirror-symmetric configuration.

A gate dielectric 132 and a gate electrode 134 form a gate structure 136. In one example, the gate structure 136 may be a “gate oxide/gate poly” gate in which the gate dielectric 132 includes silicon oxide and gate electrode 134 includes doped polysilicon. In another example, gate structure 136 may be an HKMG in which gate dielectric 132 includes a high-k dielectric and gate electrode 134 includes a metal. In some implementations, gate structures 136 are only formed in expanded VG trenches 242(b). In some implementations, gate structures 136 are formed in both unexpanded VG trenches 242(a) and expanded VG trenches 242(b) (not shown in FIG. 2K).

A dielectric material is deposited for isolating purpose between two adjacent L-shaped gate electrodes 134 in expanded VG trenches 242(b), forming isolating region 160. The dielectric material can be a same material, or a different material compared to bottom dielectric materials 246. The dielectric material can include, but not limited to, silicon oxide, silicon nitride, silicon oxynitride, low-k dielectrics, or any combination thereof. Dielectric materials can be deposited by one or more thin film deposition processes including, but not limited to, CVD, PVD, ALD, MOCVD, MBE, sputtering, or any combination thereof.

A polishing process is performed to polish away hard mask 222 (compare FIG. 2J diagram (b) with FIG. 2K diagram (b)). After polishing, the top surface of first body 171 are exposed. The polishing process can include, but not limited to, chemical mechanical polishing (CMP), mechanical polishing, electrochemical polishing, ultrasonic polishing, or any combination thereof.

As illustrated in FIG. 2L, a dielectric layer is deposited to form BL isolation 248. An array of BL trenches (not shown) is then formed in BL isolation 248 by etching. In some implementations, each BL trench extends along BL direction (X-axis) where its X dimension is longer than its Y dimension. The bottom of BL trenches along Z axis is in contact with top surfaces of transistor body 130 and top surfaces of isolating regions 160. The array of BL trenches can be distributed along the Y-axis. In some implementations, BL desolation 248 can be formed with dielectric materials including, but not limited to, silicon oxide, silicon nitride, silicon oxynitride, low-k dielectrics, or any combination thereof. Etching of BL trenches can be conducted using one or more dry etching and/or wet etching process, including, but not limited to, reactive ion etching (RIE), plasma etching, hydrofluoric acid (HF) etching, sputtering etching, KOH Etching (Potassium Hydroxide), TMAH Etching (Tetramethylammonium Hydroxide), Buffered Oxide Etchant (BOE), Piranha Solution (H2SO4/H2O2), or any combination thereof. In some implementations, the forming of BL trenches involves self-aligned double patterning (SADP).

After BL trenches are formed, a second terminal 139 is deposited into BL trenches in contact with transistor body 130, where second terminals 139 only partially fill BL trenches along Z direction. A conductive material is then deposited into BL trenches on top of second terminals 139 to form bit lines 123. A polishing process is subsequently conducted to polish away extra conductive BL materials and ensure that top surfaces of bit lines 123 are flush with top surfaces of BL isolation 248. In some implementations, the material for second terminal 139 can include, but not limited to, single crystal silicon or polysilicon with N-type (e.g., Phosphorus (P) or Arsenic (As)) or P-type dopants (e.g., Boron (B) or Gallium (Ga)) at a desired doping level, SiGe, GaAs, or any combination thereof. In some implementations, bit lines 123 are made of conductive materials, e.g., W, Co, Cu, Al, or anything combination thereof. In some implementations, the bit lines 123 are made of composite conductive material, including without limitations WSi, CoSi, CuSi, AlSi, or any other suitable metal silicides having higher conductivities than doped silicon. In some implementations, deposition of second terminal 139 and bit lines 123 can be achieved by one or more thin film deposition processes including, but not limited to electroplating, electroless plating, CVD, PVD, ALD, MOCVD, MBE, sputtering, electron-beam evaporation, or any combination thereof. In some implementations, air gaps 250 may be formed due to the relatively small pitches of bit lines 123 along the WL direction (e.g., the Y direction).

In some implementations, the second terminal 139 is part of the channel materials, e.g., IGZO, as described above. As such, a separate deposition for the second terminal materials is not required.

Referring to FIGS. 1 and 2M, an interconnect layer 122 is formed on the second semiconductor structure 104. The interconnect layer 122 can be formed by a plurality of processes including, but not limited to, photolithography, dry/wet etch, thin film deposition, thermal growth, implantation, chemical mechanical polishing (CMP), and any other suitable processes. After the interconnect layer 122 is formed, a second semiconductor structure 104 and a first semiconductor structure 102 can be jointed at bonding interface 106 therebetween.

As noted above, the first semiconductor structure 102 can include a substrate 110, which can include silicon (e.g., single crystalline silicon, c-Si), SiGe, GaAs, Ge, SOI, or any other suitable materials. The first semiconductor structure 102 can include peripheral circuits 112 on the substrate 110. In some implementations, the peripheral circuits 112 include a plurality of transistors (e.g., planar transistors and/or 3D transistors). Trench isolations (e.g., shallow trench isolations (STIs)) and doped regions (e.g., wells, sources, and drains of transistors) can be formed on or in the substrate 110 as well. In some examples, the peripheral circuits 112 are formed using complementary metal-oxide-semiconductor (CMOS) technology, and the first semiconductor structure 102 can be also formed on a semiconductor die that can be referred to as a control die or a CMOS die.

In some implementations, the first semiconductor structure 102 further includes an interconnect layer 116 above the peripheral circuits 112 to transfer electrical signals to and from the peripheral circuits 112. The interconnect layer 116 can include a plurality of interconnects (also referred to herein as “contacts”), including lateral interconnect lines and VIA contacts. The interconnect layer 116 can further include one or more interlay dielectric (ILD) layers in which the interconnect lines and via contacts can form. That is, the interconnect layer 116 can include interconnect lines and via contacts in multiple ILD layers. In some implementations, peripheral circuits 112 are coupled to one another through the interconnects in the interconnect layer 116. The interconnects in interconnect layer 116 can include conductive materials including, but not limited to, W, Co, Cu, Al, doped silicon, silicides, or any combination thereof. The ILD layers can be formed with dielectric materials including, but not limited to, silicon oxide, silicon nitride, silicon oxynitride, low-k dielectrics, or any combination thereof.

As shown in FIGS. 1 and 2M, the first semiconductor structure 102 has a front side and a back side, and the first semiconductor structure 102 can further include a bonding layer 118 at the back side of the bonding interface 106 and above the interconnect layer 116 and the peripheral circuits 112. The bonding layer 118 can include a plurality of bonding contacts 119 and dielectrics electrically isolating the bonding contacts 119. The bonding contacts 119 can include conductive materials, such as Cu. The remaining area of the bonding layer 118 can be formed with a dielectric material, such as silicon oxide. The bonding contacts 119 and surrounding dielectric material in the bonding layer 118 can be used for hybrid bonding. Similarly, as shown in FIGS. 1 and 2M, the second semiconductor structure 104 can also include a bonding layer 120 at the bonding interface 106 and above the bonding layer 118 of the first semiconductor structure 102. The bonding layer 120 can include a plurality of bonding contacts 121 and a dielectric material electrically isolating the bonding contacts 121. The bonding contacts 121 can include a conductive material, such as Cu. The remaining area of the bonding layer 120 can be formed with a dielectric material, such as silicon oxide. The bonding contacts 121 and the surrounding dielectric material in the bonding layer 120 can be used for hybrid bonding. The bonding contacts 121 can be in contact with the bonding contacts 119 at the bonding interface 106. In some implementations, the bonding layer 120 includes a dielectric layer opposing memory cells (e.g., DRAM cells) 124 with a bit line 123 positioned between the dielectric layer and the memory cells 124, as shown in FIG. 2M. The dielectric layer can include the bonding interface 106 having the bonding contacts 121.

As illustrated in FIG. 2N, the second semiconductor structure 104 is flipped over, and the substrate 201 is removed to at last partially expose supporting structures 150, first electrodes 144 and sacrificial layers 206. In some implementations, the substrate 201 is removed by a polishing process. The polishing process can include, but not limited to, chemical mechanical polishing (CMP), mechanical polishing, electrochemical polishing, ultrasonic polishing, or any combination thereof.

As illustrated in FIG. 2O, the sacrificial layers 206 are at least partially etched away, exposing first portions of capacitor cell 214. The etching can involve one or more dry etching and/or wet etching process, including, but not limited to, reactive ion etching (RIE), plasma etching, hydrofluoric acid (HF) etching, sputtering etching, KOH Etching (Potassium Hydroxide), TMAH Etching (Tetramethylammonium Hydroxide), Buffered Oxide Etchant (BOE), Piranha Solution (H2SO4/H2O2), or any combination thereof.

FIG. 2P illustrates an example configuration of pillar capacitors. A capacitor body 145 is first deposited to at least partially cover surfaces of first electrodes 144, and thus first electrode 144 is in contact with and laterally surrounded by the capacitor body 145. A second electrode 143 is then formed to at least partially cover the capacitor body 145, such that the capacitor body 145 is in contact with and laterally surrounded by the second electrode 143. In other words, the capacitor body 145 is between the first electrode 144 and the second electrode 143. After deposition, the supporting structure 150 can be between the first electrodes 144 and the second electrodes 143, or between first electrodes 144 of two adjacent capacitors 128.

A filling material 252 can be subsequently deposited to fill the gaps between different pillar capacitors. Additionally, an etching process is performed to remove unwanted portions of first electrode 144, second electrode 143, capacitor body 145 and filling material 252 in the area outside the capacitor array, as shown in FIG. 2P. In some implementations, the capacitor body 145 includes dielectric materials, such as silicon oxide, silicon nitride, or high-k dielectrics including, but not limited to, Al2O3, HfO2, Ta2O5, ZrO2, TiO2, or any combination thereof. In some implementations, the second electrode 143 includes a same conductive material as the first electrode 144, including, but not limited to, SiGe, W, Co, Cu, Al, TIN, TaN, polysilicon, silicide, or any combination thereof. In some implementations, the first electrode 144 includes TiN, and the second electrode 143 includes two or more conductive layers, such as a SiGe layer over a TiN layer. In some implementations, filling material 252 can include a dielectric material, including but not limited to, silicon oxide, silicon nitride, low-k dielectric, or high-k dielectrics, or any combination thereof.

FIG. 2Q and FIG. 1 are identical figures, differing only in the polarity of Z axis. In FIG. 1, the positive Z axis is upward, whereas in FIG. 2Q the positive Z axis is downward (due to substrate 201 flipping in FIG. 2N). However, this reversal of the z-axis polarity has no meaningful impact on exemplary configuration of 3D semiconductor devices.

As illustrated in FIG. 2Q, the second semiconductor structure 104 can further include a pad-out interconnect layer 156 above capacitors 128 and DRAM cells 124. The pad-out interconnect layer 156 can include interconnects, e.g., contact pads 154, in one or more ILD layers. The second semiconductor structure 104 can further include a capacitor contact 147 (e.g., a conductor) in contact with a common plate 146 for coupling the capacitors 128 to the peripheral circuits 112 or to the ground directly. In some implementations, the capacitor contact 147 (e.g., a conductor) extends in the z-direction from the dielectric layer of the bonding layer 120 to couple to the second end of the capacitor 128 via the common plate 146. In some implementation, the ILD layer in which the capacitors 128 are formed has the same dielectric material as the ILD layers into which the transistor body 130 extends, such as silicon oxide.

Although not shown in FIG. 2Q and FIG. 1, it is understood that, in some implementations, the capacitors 128 and/or the vertical transistors 126 can have a trapezoid cross-section in X-Z plane. As noted above, referring to FIG. 2R, a first body end 230 of a vertical transistor 126 can be narrower than a second body end 232 of the vertical transistor 126, while the first capacitor end 234 can be wider than the second capacitor end 236.

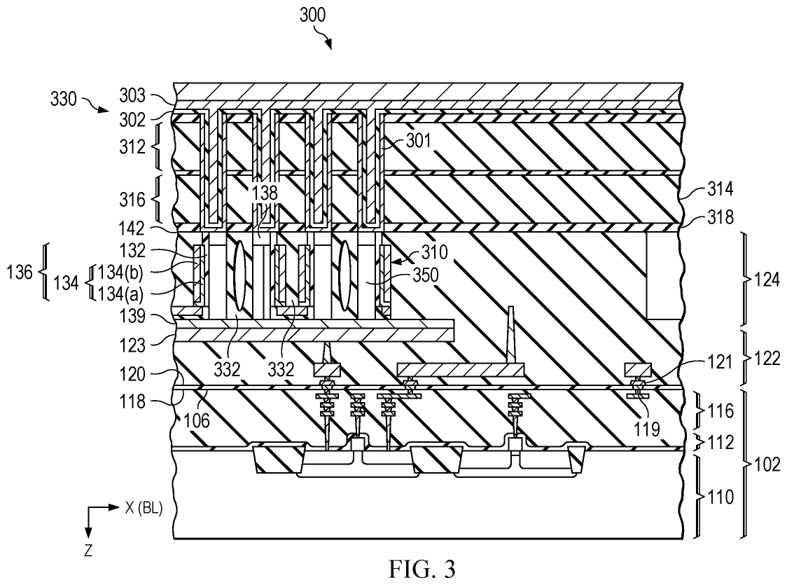

Although only pillar capacitors are illustrated in FIGS. 2A-2R, it is understood that the techniques implemented herein can be applied to other types of capacitors, e.g., cup capacitors, or cup capacitors based 3D memory devices. FIG. 3 illustrates an example configuration of cup capacitors 330. First electrode 301 of a cup capacitor 330 can be on inner surfaces of capacitor trenches. Second electrode 303 of the cup capacitor330 can have a “T” shape, where a first portion of “T” shape extends vertically along z axis and a second portion of “T” shape extends laterally along x axis (e.g., BL direction). The first electrode 301 of the cup capacitor 330 can be isolated from the second electrode 303 by a capacitor body 302 of the cup capacitor 330. Similar to the formation process of pillar capacitors in FIGS. 2A-2Q, the first electrode 301 of the cup capacitor 330 can be formed prior to the formation of vertical transistors 310, while the second electrode 303 of the cup capacitor 330 and the capacitor body 202 of the cup capacitor 330 can be formed after the formation of vertical transistor 310. In some implementations, the first electrode 301 of the cup capacitor 330 and the second electrode 303 of the cup capacitor 330 include a same material or different materials. In some implementations, the first electrode 301 and the second electrode 303 include a conductive material including, but not limited to, SiGe, W, Co, Cu, Al, TiN, TaN, polysilicon, silicide, or any combination thereof. In some implementations, at least one of the first electrode 301 or the second electrode 303 includes multiple conductive layers, such as a SiGe layer over a TiN layer. In some implementations, the capacitor body 302 includes a dielectric material, such as silicon oxide, silicon nitride, or high-k dielectrics including, but not limited to, Al2O3, HfO2, Ta2O5, ZrO2, TiO2, or any combination thereof.

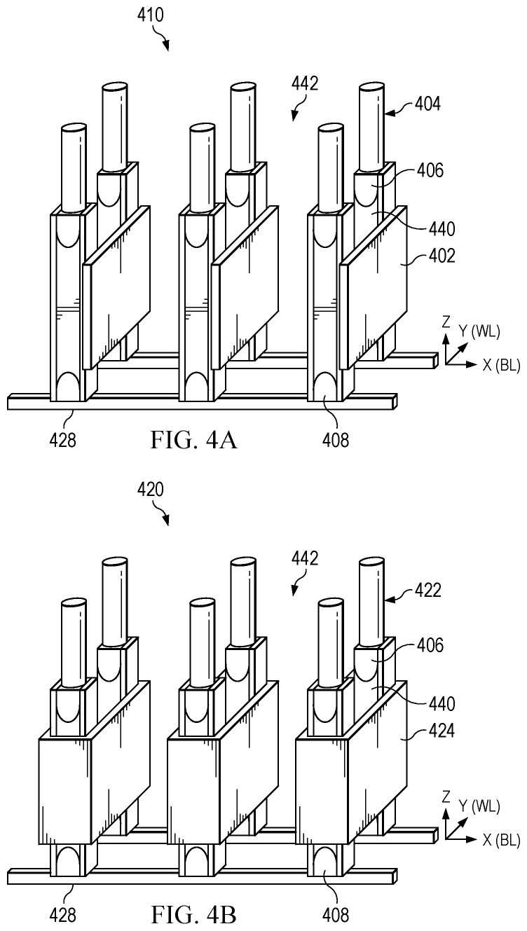

Although FIGS. 2A-2R only illustrate a mirror-symmetric gate configuration, it is understood that other arrangements of gate electrodes can be employed, including, but not limited to, single-side gate structure, a dual-side gate structure, a triple-side gate structure, or a gate-all-around (GAA) structure. FIG. 4A illustrates a single-side gate, where a gate electrode 402 is consistently formed on one lateral side of vertical transistors 404, e.g., the right hand side in a positive X direction. FIG. 4B illustrates a dual-side gate configuration, where gate electrodes 424 are formed on both lateral sides of vertical transistor 422, e.g., in both positive and negative X directions. Although not shown in FIGS. 4A and 4B, it is understood that, in some implementations, gate electrodes, e.g., 402 in FIG. 4A or 424 in FIG. 4B, have an angled or curved end, e.g., L-shape. In some examples, a L-shaped gate electrode has a first portion extending along the X direction and a second portion extending along Z direction or along an inclined angle relative to the Z direction, where the first portion extending along X direction is closer to the first terminals 406, e.g., source terminals, compared to second terminals 408, e.g., drain terminals. In some implementations, gate electrodes, e.g., 402 in FIG. 4A or 424 in FIG. 4B, include a conductive material including, but not limited to, W, Co, Cu, Al, TiN, TaN, polysilicon, silicide, or any combination thereof. In some implementations, gate electrodes, e.g., 402 in FIG. 4A or 424 in FIG. 4B, include two or more conductive layers, such as a W layer over a TiN layer.

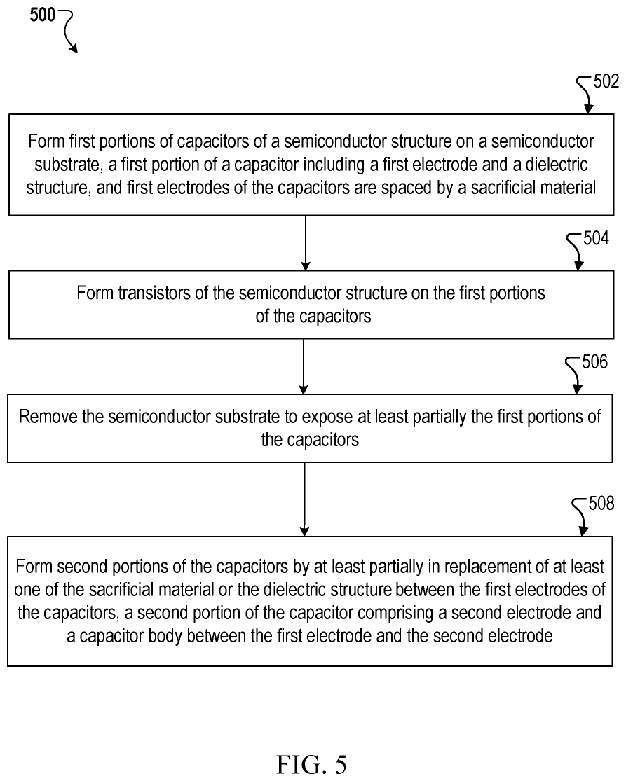

FIG. 5 is a flow chart of an example process 500 of forming a 3D semiconductor device. The 3D semiconductor device can be similar to, or same as, the 3D semiconductor device 100 of FIG. 1, or a part of the 3D semiconductor device 100 (e.g., the second semiconductor structure 104 of FIG. 1), or a structure at an intermediate fabrication process of the 3D semiconductor device 100 of FIG. 1, or the semiconductor structure 300 of FIG. 3, or the 3D semiconductor structure 410 of FIG. 4A, or the 3D semiconductor structure 420 of FIG. 4B. The process 500 can be described in view of FIGS. 2A-2R. The process 500 can include the fabrication process of forming the 3D semiconductor structure in FIGS. 2A-2R. The process 500 includes steps that can be performed with any suitable order and/or any combination.

At step 502, first portions of capacitors of a semiconductor structure are formed on a semiconductor substrate, where a first portion of a capacitor includes a first electrode and a dielectric structure, and first electrodes of the capacitors are spaced by a sacrificial layer. The first portions of the capacitors can be, e.g., first portions of capacitors 214 in FIGS. 2F-2O, or first portions of capacitors 316 in FIG. 3. The semiconductor structure can be, e.g., a second semiconductor structure 104 in FIGS. 1 and 2A-2R. The semiconductor substrate can be, e.g., the substrate 201 in FIGS. 1 and 2A-2M. The first electrode can be, e.g., first electrodes 144 in FIGS. 1 and 2D-2R, or first electrodes of cup capacitors 301 in FIG. 3. The dielectric structure can be, e.g., the dielectric structure 149 of FIGS. 2D-2R. The sacrificial materials can be, e.g., sacrificial layers 206 in FIG. 2B-2N, or sacrificial layers 314 in FIG. 3. The semiconductor substrate 201 can include silicon (e.g., single crystalline silicon, c-Si), SiGe, GaAs, Ge, SOI, or any other suitable materials. The electrode materials can include, but not limited to, TiN, TaN, Al, W, Cu, doped-polysilicon, silicides, or any combination thereof. The sacrificial layers can be formed with dielectric materials including, but not limited to, silicon oxide, silicon nitride, silicon oxynitride, low-k dielectrics, or any combination thereof.

In some implementations, forming the first portions of the capacitors of the semiconductor structure on the semiconductor substrate includes: forming an array of holes through one or more dielectric layers on the semiconductor substrate, depositing a first conductive film on surfaces of the array of holes, and filling a dielectric material into the array of holes by depositing the dielectric material on the first conductive film to form dielectric structures of the capacitors. A dielectric structure of the dielectric structures has a first end and a second end opposite to each other. The first end is closer to a transistor than the second end, and the first end has a greater size than the second end (see FIG. 2R). The dielectric layers are spaced by an isolating material. The dielectric layer can be, e.g., sacrificial layer 206 of FIGS. 2A-2N, or sacrificial layer 314 of FIG. 3. The array of holes can be, e.g., capacitor trench 208 of FIGS. 2C-2R, or capacitor trench 340 of FIG. 3. The dielectric structure can be the dielectric structure 149 of FIG. 2D-2R. The conductive film can be, e.g., first electrodes 144 in FIGS. 1 and 2D-2R, or first electrodes of cup capacitors 301 in FIG. 3.

At step 504, vertical transistors of the semiconductor structures are formed on the top of the first portions of the capacitors. The vertical transistors can be, e.g., the vertical transistors 126 in FIGS. 1 and 2K-2Q, vertical transistors 310 in FIG. 3, vertical transistors 404 in FIG. 4A, or vertical transistors 422 in FIG. 4B. Each vertical transistor extends along a vertical direction (e.g., Z direction); two adjacent vertical transistors and a corresponding isolating region between the two adjacent vertical transistors are positioned along a first lateral direction (e.g., X direction) perpendicular to the vertical direction. The first portions of the capacitors can be, e.g., the first portions of capacitors 214 in FIGS. 2F-2N, or the first portion of capacitors 316 in FIG. 3.

In some implementations, forming the vertical transistors of the semiconductor structures on the first portions of the capacitors includes: forming transistor bodies of the transistors, the transistor bodies being coupled to the first electrodes of the capacitors, forming vertical gates of the transistors adjacent to the transistor bodies of the transistors, and forming an isolating region between two adjacent transistors. The isolating region has a first end close to the first electrodes of the capacitors and a second end opposite to the first end along a first direction, and the first end has a smaller size than the second end (see FIG. 2R). The transistor bodies can be, e.g., body 220 of FIGS. 2H-2R, body 350 of FIG. 3, or body 440 of FIGS. 4A-4B. The isolating region can be, e.g., the isolating region 160 of FIGS. 2K-2Q, isolating region 332 of FIG. 3, or isolating region 442 of FIGS. 4A-4B.

In some implementations, forming the transistors of the semiconductor structure on the first portions of the capacitors further includes: forming a conductive layer on the first portions of capacitors, annealing the conductive layer, where a conductive material of the conductive layer reacts with the first electrodes of the capacitors to form a composite conductive material, forming a body on the conductive layer, and forming trenches extending through the layer of the composite conductive material and the body to form the first terminals of the transistors and the transistor bodies of the transistors, respectively. The first terminal can be, e.g., the first terminal 138 of FIGS. 2H-2Q, the first terminal 334 of FIG. 3, or first terminal 406 of FIGS. 4A-4B. The trenches can be, e.g., body trench 226 of FIGS. 2I-2R, body trench 336 of FIG. 3, or body trench 444 of FIGS. 4A-4B.

In some implementations, the method for forming a semiconductor device further includes: forming bit lines on second terminals of the transistors, forming at least conductive interconnect layer on the bit lines, bonding the semiconductor structure with a control structure by bonding a surface of the at least conductive interconnect layer with a surface of control circuitry of the control structure. The bit lines can be, e.g., bit line 123 of FIG. 1, 2L-2Q, bit line 338 of FIG. 3, or bit line 428 of FIGS. 4A-4B. The second terminal can be, e.g., second terminal 139 of FIGS. 1, 2L-2Q, or second terminal 408 of FIGS. 4A-4B. The control structure can be, e.g., the first semiconductor structure 102 of FIGS. 1, 2M-2Q.

At step 506, the semiconductor substrate (e.g., the substrate 201 in FIGS. 2A-2M) is removed to expose at least partially the first portions of the capacitors. The first portions of the capacitors can be, e.g., the first portions of capacitors 214 in FIGS. 2F-2N, or the first portion of capacitors 316 in FIG. 3.

At step 508, second portions of the capacitors are formed by at least partially in replacement of at least one of the sacrificial material or the dielectric structure between the first electrodes of the capacitors, the second portions of the capacitor comprising a second electrode, and a capacitor body between the first electrode and the second electrode. The second portions of the capacitors can be, e.g., second portions of capacitor cells 260 in FIGS. 2P-2Q, or second portions of capacitors 312 in FIG. 3. The sacrificial materials can be, e.g., sacrificial layer 206 in FIG. 2B-2N, or sacrificial layer 314 in FIG. 3. The dielectric structure can be, e.g., the dielectric structure 149 of FIGS. 2D-2R. The first electrodes of the capacitors can be, e.g., first electrode 144 in FIGS. 1 and 2D-2R, or first electrodes of cup capacitors 301 in FIG. 3. The second electrodes can be, e.g., second electrode 143 in FIGS. 1 and 2P-2Q, or second electrodes of cup capacitors 303 in FIG. 3. The capacitor body can be, e.g., capacitor body 145 in FIGS. 1 and 2P-2Q, or capacitor body of cup capacitors 302 in FIG. 3.

In some implementations, the capacitors are pillar capacitors, e.g., the capacitor 128 of FIGS. 2P-2Q. Forming the second portions of the capacitors can include the following process steps: at least partially removing the sacrificial material between the first electrodes of the capacitors, depositing a dielectric material on the first electrodes to form the capacitor bodies of the capacitors and depositing at least one conductive film on the dielectric material to form the second electrodes of the capacitors. The sacrificial materials can be, e.g., sacrificial layer 206 in FIG. 2B-2N. The capacitor bodies can be, e.g., the capacitor body 145 of FIGS. 2P-2Q. The second electrodes of the capacitors can be, e.g., the second electrode 143 of FIGS. 2P-2Q.

In some implementations, the capacitors are cup capacitors, e.g., the capacitors 330 of FIG. 3. Forming the second portions of the capacitors can include the following process steps: removing a portion of the first electrodes to expose an end of the dielectric structure (e.g., as illustrated in FIG. 3), removing at least part of dielectric structure to form trenches; depositing a dielectric material on the first electrodes in the trenches to form the capacitor bodies of the capacitors (e.g., the capacitor bodies 302 of FIG. 3), and depositing at least one conductive film in the trenches to form second electrodes of cup capacitors (e.g., the second electrodes 303 of FIG. 3). As noted above, a second electrode of cup capacitors can have a “T” shape, where a first potion of “T” shape is extending vertically along z direction and a second portion of “T” shape is extending laterally along x direction. The first electrode of a cup capacitor (e.g., the first electrode 301 of FIG. 3) can be isolated from the second electrode by a capacitor body of the cup capacitor. In some implementations, the first electrode and the second electrode of the cup capacitor include a same material. In some implementations, the first electrode and the second electrode include different materials. In some implementations, the first electrode and the second electrode include a conductive material including, but not limited to, SiGe, W, Co, Cu, Al, TiN, TaN, polysilicon, silicide, or any combination thereof. In some implementations, at least one of the first electrode or the second electrode includes multiple conductive layers, such as a SiGe layer over a TiN layer. In some implementations, the capacitor body includes a dielectric material, such as silicon oxide, silicon nitride, or high-k dielectrics including, but not limited to, Al2O3, HfO2, Ta2O5, ZrO2, TiO2, or any combination thereof.

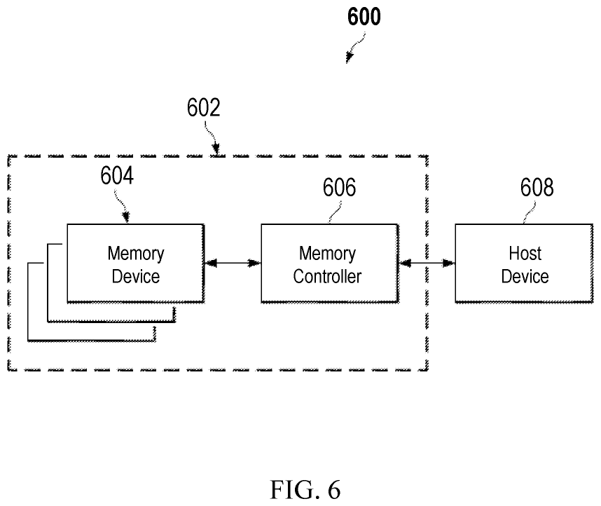

FIG. 6 illustrates a block diagram of a system 600 having one or more semiconductor devices (e.g., memory devices), according to one or more implementations of the present disclosure. The system 600 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 6, the system 600 can include a host device 608 and a memory system 602 having one or more 3D memory devices 604 and a memory controller 606. Host device 608 can include a processor of an electronic device, such as a central processing unit (CPU), or a system-on-chip (SoC), such as an application processor (AP). Host device 608 can be configured to send or receive data to or from the one or more 3D memory devices 604.

A 3D memory device 604 can be any 3D memory device disclosed herein, such as the 3D semiconductor device 100 of FIG. 1, or a part of the 3D semiconductor device 100 (e.g., the second semiconductor structure 104 of FIG. 1), or a structure at an intermediate fabrication process of the 3D semiconductor device 100 of FIG. 1, or the semiconductor structure 300 of FIG. 3, or the 3D semiconductor structure 410 of FIG. 4A, or the 3D semiconductor structure 420 of FIG. 4B. In some implementations, a 3D memory device 604 includes a NAND Flash memory. Memory controller 606 (a.k.a., a controller circuit) is coupled to 3D memory device 604 and host device 608. Consistent with implementations of the present disclosure, 3D memory device 604 can include a plurality of conductive interconnections through a cover layer that are in contact with conductive pads in a conductive pad layer, and memory controller 606 can be coupled to 3D memory device 604 through at least one of the plurality of conductive interconnections. Memory controller 606 is configured to control 3D memory device 604. For example, memory controller 606 may be configured to operate a plurality of channel structures via word lines. Memory controller 606 can manage data stored in 3D memory device 604 and communicate with host device 608.

In some implementations, memory controller 606 is designed/configured for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 606 is designed/configured for operating in a high duty cycle environment SSDs or embedded multi-media-cards (eMMCs) used as data storage for mobile devices, such as smartphones, tablets, laptop computers, etc., and enterprise storage arrays. Memory controller 606 can be configured to control operations of 3D memory device 604, such as read, erase, and program (or write) operations. Memory controller 606 can also be configured to manage various functions with respect to the data stored or to be stored in 3D memory device 604 including, but not limited to bad-block management, garbage collection, logical-to-physical address conversion, wear leveling, etc. In some implementations, memory controller 606 is further configured to process error correction codes (ECCs) with respect to the data read from or written to 3D memory device 604. Any other suitable functions may be performed by memory controller 606 as well, for example, formatting 3D memory device 604.

Memory controller 606 can communicate with an external device (e.g., host device 608) according to a particular communication protocol. For example, memory controller 606 may communicate with the external device through at least one of various interface protocols, such as a USB protocol, an MMC protocol, a peripheral component interconnection (PCI) protocol, a PCIexpress (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 606 and one or more 3D memory devices 604 can be integrated into various types of storage devices, for example, be included in the same package, such as a universal Flash storage (UFS) package or an eMMC package. That is, memory system 602 can be implemented and packaged into different types of end electronic products. In one example as shown in FIG. 6, memory controller 606 and a single 3D memory device 604 may be integrated into a memory card 602. Memory card 602 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc.

Implementations of the subject matter and the actions and operations described in this present disclosure can be implemented in digital electronic circuitry, in tangibly-embodied computer software or firmware, in computer hardware, including the structures disclosed in this present disclosure and their structural equivalents, or in combinations of one or more of them. Implementations of the subject matter described in this present disclosure can be implemented as one or more computer programs, e.g., one or more modules of computer program instructions, encoded on a computer program carrier, for execution by, or to control the operation of, data processing apparatus. The carrier may be a tangible non-transitory computer storage medium. Alternatively, or in addition, the carrier may be an artificially-generated propagated signal, e.g., a machine-generated electrical, optical, or electromagnetic signal, that is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

It is noted that references in the present disclosure to “one embodiment,” “an embodiment,” “an example embodiment,” “some implementations,” “some implementations,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for ease of description to describe one element or feature's relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layers.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g., .+−. 10%, .+−. 20%, or .+−. 30% of the value).

In the present disclosure, the term “horizontal/horizontally/lateral/laterally” means nominally parallel to a lateral surface of a substrate, and the term “vertical” or “vertically” means nominally perpendicular to the lateral surface of a substrate.

As used herein, the term “3D memory” refers to a three-dimensional (3D) semiconductor device with vertically oriented strings of memory cell transistors (referred to herein as “memory strings,” such as NAND strings) on a laterally-oriented substrate so that the memory strings extend in the vertical direction with respect to the substrate.

The present disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include implementations in which the first and second features may be in direct contact, and may also include implementations in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various implementations and/or configurations discussed.

The foregoing description of the specific implementations can be readily modified and/or adapted for various applications. Therefore, such adaptations and modifications are intended to be within the meaning and range of equivalents of the disclosed implementations, based on the teaching and guidance presented herein.

While the present disclosure contains many specific implementation details, these should not be construed as limitations on the scope of what is being claimed, which is defined by the claims themselves, but rather as descriptions of features that may be specific to particular implementations of particular inventions. Certain features that are described in this present disclosure in the context of separate implementations can also be implemented in combination in a single embodiment. Conversely, various features that are described in the context of a single embodiment can also be implemented in multiple implementations separately or in any suitable sub-combination. Moreover, although features may be described above as acting in certain combinations and even initially be claimed as such, one or more features from a claimed combination can in some cases be excised from the combination, and the claim may be directed to a sub-combination or variation of a sub-combination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations also are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

The breadth and scope of the present disclosure should not be limited by any of the above-described exemplary implementations, but should be defined only in accordance with the following claims and their equivalents.

What is claimed is:

1. A semiconductor device, comprising:
an array structure comprising a plurality of memory cells, wherein a memory cell of the plurality of memory cells comprises a transistor and a capacitor that are stacked together along a first direction,
wherein the transistor comprises a transistor body, a first terminal, a second terminal, and a gate structure, the first terminal and the second terminal being on opposite ends of the transistor body along the first direction, the gate structure extending along the first direction and being adjacent to the transistor body along a second direction perpendicular to the first direction,
wherein the first terminal of the transistor is in contact with a first electrode of the capacitor along the first direction, and
wherein the gate structure comprises a conductive film having an angled or curved end closer to the first terminal of the transistor than the second terminal of the transistor.

2. The semiconductor device of claim 1, wherein the transistor body comprises a first body and a second body that are in contact with each other along the second direction, and
wherein the second body has a higher electron mobility than the first body, and the second body is closer to the gate structure than the first body.

3. The semiconductor device of claim 2, wherein the first body comprises amorphous silicon, and the second body comprises at least one of polycrystalline silicon, indium gallium zinc oxide (IGZO), or indium gallium silicon oxide (IGSO).

4. The semiconductor device of claim 1, wherein the transistor body comprises at least one of polycrystalline silicon, indium gallium zinc oxide (IGZO), or indium gallium silicon oxide (IGSO).

5. The semiconductor device of claim 1, wherein the array structure comprises an isolating region that is between transistors of two adjacent memory cells of the plurality of memory cells,
wherein the isolating region has a first end close to first terminals of the transistors and a second end close to second terminals of the transistors, and the first end has a smaller size than the second end.

6. The semiconductor device of claim 1, wherein the capacitor comprises a dielectric structure extending along the first direction, and the first electrode is on at least one surface of the dielectric structure, and
wherein the dielectric structure has a first end and a second end opposite to each other along the first direction, and wherein the first end is closer to the first terminal of the transistor than the second end, and the first end has a greater size than the second end.

7. The semiconductor device of claim 6, wherein the capacitor further comprises a second electrode and a capacitor body between the first electrode and the second electrode,
wherein the first electrode encloses the dielectric structure, the capacitor body covers the first electrode, and the second electrode covers the capacitor body, and
wherein the array structure comprises supporting structures extending along the second direction and being distributed along the first direction between the first electrode and the second electrode or between first electrodes of two adjacent capacitors.

8. The semiconductor device of claim 1, wherein the array structure further comprises a plurality of bit lines, and one of the plurality of bit lines is in contact with the second terminal of the transistor, and adjacent bit lines are isolated by a corresponding isolating region.

9. The semiconductor device of claim 8, wherein the array structure is integrated in a first die, and the semiconductor device further comprises a second die,
wherein the first die comprises at least one conductive interconnection, through which the one of the plurality of bit lines is coupled to a control circuit in the second die,
wherein a surface of a cover layer over the plurality of bit lines in the first die is in contact with a surface of the control circuit in the second die, and
wherein the plurality of bit lines is closer to the second die than the capacitor.

10. A semiconductor device, comprising:
an array structure comprising a plurality of memory cells, wherein a memory cell of the plurality of memory cells comprises a transistor and a capacitor that are stacked together along a first direction,
wherein the transistor comprises a transistor body, a first terminal, a second terminal, and a gate structure, the first terminal and the second terminal being on opposite ends of the transistor body along the first direction, the gate structure extending along the first direction and being adjacent to the transistor body along a second direction perpendicular to the first direction,
wherein the transistor body comprises at least one of polycrystalline silicon, indium gallium zinc oxide (IGZO), or indium gallium silicon oxide (IGSO),
wherein the first terminal of the transistor is in contact with a first electrode of the capacitor along the first direction, and
wherein the capacitor comprises a dielectric structure extending along the first direction, the first electrode is on at least one surface of the dielectric structure, and the dielectric structure has a first end and a second end opposite to each other along the first direction, and wherein the first end of the dielectric structure is closer to the first terminal of the transistor than the second end of the dielectric structure, and the first end of the dielectric structure has a greater size than the second end of the dielectric structure along the second direction.

11. The semiconductor device of claim 10, wherein the array structure comprises an isolating region that is between transistors of two adjacent memory cells of the plurality of memory cells, and wherein the isolating region has a first end close to first terminals of the transistors and a second end close to second terminals of the transistors, and the first end has a smaller size than the second end.

12. The semiconductor device of claim 10, wherein the gate structure comprises a conductive film having an angled or curved end closer to the first terminal of the transistor than the second terminal of the transistor.

13. The semiconductor device of claim 11, wherein the capacitor further comprises a second electrode and a capacitor body between the first electrode and the second electrode,
wherein the first electrode encloses the dielectric structure, the capacitor body covers the first electrode, and the second electrode covers the capacitor body, and
wherein the array structure comprises supporting structures extending along the second direction and being distributed along the first direction between the first electrode and the second electrode or between first electrodes of two adjacent capacitors.

14. The semiconductor device of claim 10, wherein the array structure further comprises a plurality of bit lines, and one of the plurality of bit lines is in contact with the second terminal of the transistor, and adjacent bit lines are isolated by a corresponding isolating region,
wherein the array structure is integrated in a first die, and the semiconductor device further comprises a second die,
wherein the first die comprises at least one conductive interconnection, through which the one of the plurality of bit lines is coupled to a control circuit in the second die,
wherein a surface of a cover layer over the plurality of bit lines in the first die is in contact with a surface of the control circuit in the second die, and
wherein the plurality of bit lines is closer to the second die than the capacitor.

15. A method comprising:
forming first portions of capacitors of a semiconductor structure on a semiconductor substrate, wherein a first portion of a capacitor comprises a first electrode and a dielectric structure, and first electrodes of the capacitors are spaced by a sacrificial material;
forming transistors of the semiconductor structure on the first portions of the capacitors;
removing the semiconductor substrate to expose at least partially the first portions of the capacitors; and
forming second portions of the capacitors by at least partially in replacement of at least one of the sacrificial material or the dielectric structure between the first electrodes of the capacitors, wherein a second portion of the capacitor comprises a second electrode and a capacitor body between the first electrode and the second electrode.

16. The method of claim 15, wherein forming second portions of the capacitors by at least partially in replacement of at least one of the sacrificial material or the dielectric structure between the first electrodes of the capacitors comprises:
at least partially removing the sacrificial material between the first electrodes of the capacitors,
depositing a dielectric material on the first electrodes to form the capacitor bodies of the capacitors, and
depositing at least one conductive film on the dielectric material to form the second electrodes of the capacitors.

17. The method of claim 15, wherein forming the transistors of the semiconductor structure on the first portions of the capacitors comprises:
forming transistor bodies of the transistors, the transistor bodies being coupled to the first electrodes of the capacitors;
forming vertical gates of the transistors adjacent to the transistor bodies of the transistors; and
forming an isolating region between two adjacent transistors, wherein the isolating region has a first end close to the first electrodes of the capacitors and a second end opposite to the first end along a first direction, and the first end has a smaller size than the second end.

18. The method of claim 17, wherein forming the transistors of the semiconductor structure on the first portions of the capacitors comprises:
forming a conductive layer on the first portions of capacitors;
annealing the conductive layer, such that a conductive material of the conductive layer reacts with the first electrodes of the capacitors to form a composite conductive material;
forming a body on the conductive layer; and
forming trenches extending through the layer of the composite conductive material and the body to form first terminals of the transistors and the transistor bodies of the transistors, respectively.

19. The method of claim 17, further comprising:
forming bit lines on second terminals of the transistors;
forming at least conductive interconnect layer on the bit lines; and
bonding the semiconductor structure with a control structure by bonding a surface of the at least conductive interconnect layer with a surface of control circuitry of the control structure.

20. The method of claim 17, wherein forming the first portions of the capacitors of the semiconductor structure on the semiconductor substrate comprises:
forming an array of holes through one or more dielectric layers on the semiconductor substrate, wherein the dielectric layers are spaced by an isolating material;
depositing a first conductive film on surfaces of the array of holes; and
filling a dielectric material into the array of holes by depositing the dielectric material on the first conductive film to form dielectric structures of the capacitors,
wherein a dielectric structure of the dielectric structures has a first end and a second end opposite to each other, and wherein the first end is closer to a transistor than the second end, and the first end has a greater size than the second end.
